(19) United States
(12) Patent Application Publication
(10) Pub. No.: US 2001/0008298 A1
(43) Pub. Date: Jul. 19, 2001

(54) Semiconductor device and method of manufacturing same

(76) Inventor: Fumihiko Sato, Tokyo (JP)

Correspondence Address: SUGHRUE, MION, ZINN, MACPEAK & SEAS, 2100 Pennsylvania Avenue, N.W., Washington, DC, 20037-3202, US

(21) Appl. No.: 09/757,484

(22) Filed: Jan. 11, 2001

(30) Foreign Application Priority Data
Jan. 12, 2000 (JP) 2000-003108

(51) Int. Cl. H01L 27/082; H01L 31/11; H01L 21/8238; H01L 21/331; H01L 27/102; H01L 21/8222; H01L 29/70

(52) U.S. Cl. 257/578; 257/566; 438/205; 438/313

(57) ABSTRACT

A method of manufacturing a semiconductor device simultaneously forms a first vertical bipolar transistor which operates at a relatively low speed and is of a high withstand voltage and a low power requirement and a second vertical bipolar transistor which operates at a relatively high speed and is of a high power requirement. The method comprises the steps of forming openings for selectively forming single crystal base regions respectively in the vertical bipolar transistors, forming single crystal base regions via the openings, forming an insulating film on a device forming surface of a semiconductor substrate after the base regions are formed, and introducing ions of an impurity of the same conductivity type as a collection region via the insulating film. The opening in the second vertical bipolar transistor is of a size greater than the opening in the first vertical bipolar transistor.

### BACKGROUND OF THE INVENTION

1. Field of the Invention

The present invention relates to a semiconductor device and a method of manufacturing a semiconductor device, and more particularly to a semiconductor device including bipolar transistors and a method of manufacturing such a semiconductor device.

2. Description of the Prior Art

Bipolar transistors are typical of semiconductor devices capable of high-speed operation. However, the high speed of operation of a bipolar transistor is a trade-off for the withstand voltage of the bipolar transistor.

For example, one indicator of the high-speed operation of a bipolar transistor is a cut-off frequency f_{T} at which the common emitter current gain h_{fe} is 1. While there are available several indicators of the withstand voltage of the bipolar transistor, an emitter-to-collector withstand voltage BV_{CEO} will be used hereinbelow. If base regions of bipolar transistors are formed according to the same process, then the product of the cut-off frequency f_{T} and the emitter-to-collector withstand voltage BV_{CEO}, i.e., “f_{T}×BV_{CEO}”, is of a substantially constant value. For bipolar transistors using silicon (Si) as their semiconductor material, the product is at most approximately 200 GHz.V. For standard Si bipolar transistors, the product ranges from 120 to 150 GHz.V.

It is semi-experimentally known in the art that the emitter-to-collector withstand voltage BV_{CEO} is proportional to an emitter-open, collector-to-base withstand voltage BV_{CBO} and inversely proportional to one-third root through one-fourth root of the common emitter current gain h_{fe}, i.e., expressed as BV_{CEO}= BV_{CBO}/(h_{fe})ⁿ where n=⅓to ¼(see A. S. Grove, “Physics and Technology of Semiconductor Devices”, JOHN WILEY & SONS, p. 233).

It is assumed that a plurality of bipolar transistors are formed on one semiconductor substrate to make up circuits. Of the bipolar transistors, those used in an emitter-grounded circuit and having a collector to which a large voltage is applied should preferably be constructed with a reduced impurity concentration in the collector region for keeping a desired withstand voltage. In order to produce different impurity concentrations in the collector regions of a plurality of transistors, it has been customary to selectively cover the collector regions with a photoresist to fabricate transistors having a higher cut-off frequency f_{T} and a lower withstand voltages and transistors having a lower cut-off frequency f_{T} and a higher withstand voltages.

Conventional transistor fabrication processes will be described below with reference to FIGS. 1A to 1D and FIGS. 2A to 2D, which show successive steps of the fabrication processes in vertical cross section. FIGS. 1A to 1D show the fabrication process for transistors which are of a relatively low power requirement and low in speed, and FIGS. 2A to 2D show the fabrication process for transistors which are of a relatively high power requirement and high in speed.

First, a base region of a bipolar transistor is formed. As shown in FIGS. 1A and 2A, a base region is formed by selective epitaxial growth. Alternatively, a base region may be formed by ion implantation, which is a general base forming method, rather than selective epitaxial growth.

Then, as shown in FIGS. 1B and 2B, a silicon oxide film is deposited by LPCVD (Low Pressure Chemical Vapor Deposition). Thereafter, as shown in FIG. 1B, one of the transistors is covered with a photoresist film. Then, phosphorus (P) is introduced into a collector region beneath the base region by ion implantation in order to achieve optimum operating characteristics with a high current.

It is known in the art that the operating current density j_{c} (A/cm⁻²) of the transistor and the impurity concentration N_{c} (cm⁻³) of the collector region are related to each other by:

j_{c}=q×μ_{c}×E_{c}×N_{c}=q×Vₛ×N_{c}

where q represents an elementary electric charge [=1.6×10⁻¹⁹ C], μ_{c} the charge mobility, E_{c} the electric field, and Vₛ the saturation speed (see S. M. Sze, “Physics of Semiconductor Devices”, JOHN WILEY & SONS, 2nd edition, 1981, p. 160). For example, if the collector impurity concentration N_{c} is about 1×10¹⁷ cm⁻³, then operating current density j_{c} is j_{c}=1 mA/μ m⁻².

After the photoresist film is removed, as shown in FIGS. 1C and 2C, the silicon oxide film is etched back to form side walls. Thereafter, as shown in FIGS. 1D and 2D, a polycrystalline silicon film for an emitter electrode is formed by CVD (Chemical vapor Deposition) to form an emitter in place.

According to the conventional transistor fabrication processes, a photolithographic process is needed to cover a transistor region where the impurity concentration in a certain collection region is not to be changed, with respect to the ion implantation step for changing the impurity concentration in another collector region.

### SUMMARY OF THE INVENTION

It is therefore an object of the present invention to provide a semiconductor device capable of simultaneously producing a high-performance high-power transistor and a high-withstand-voltage low-power transistor without the need for an additional photolithographic process.

Another object of the present invention to provide a method of manufacturing a semiconductor device capable of simultaneously producing a high-performance high-power transistor and a high-withstand-voltage low-power transistor without the need for an additional photolithographic process.

The first object can be achieved by a semiconductor device which comprises a plurality of bipolar transistors designed to exhibit respective optimum electric characteristics at different current densities, the bipolar transistors having respective emitters, wherein the emitters have greater dimensions for bipolar transistors designed to be used at higher current densities.

The first object can be also achieved by a semiconductor device which comprises a plurality of vertical bipolar transistors designed to exhibit respective optimum electric characteristics at different current densities and a semiconductor substrate on which the vertical bipolar transistors are disposed, the vertical bipolar transistors comprising respective collector regions, respective base regions, and respective emitter regions successively disposed on the semiconductor substrate, the emitter regions having respective substantially rectangular shapes in plan, wherein the substantially rectangular shapes include shorter sides having greater dimensions for bipolar transistors designed to be used at higher current densities.

The second object can be achieved by a method of manufacturing a semiconductor device having, on one semiconductor substrate, a first vertical bipolar transistor operable at a relatively low current density and a second vertical bipolar transistor operable at a relatively high current density, the method comprising the steps of forming openings for selectively forming single crystal base regions respectively in the first and second vertical bipolar transistors, and forming single crystal base regions via the openings, the opening in the second vertical bipolar transistor having a size greater than the opening in the first vertical bipolar transistor.

The present invention provides a method of manufacturing a semiconductor device, which is capable of forming a high-withstand-voltage bipolar transistor without an additional photolithography process at the same time that a high-performance vertical npn bipolar transistor is formed. The present invention is thus concerned with the structure of bipolar transistors and a method of manufacturing bipolar transistors, and serves the purpose of simultaneously fabricating a bipolar transistor which is of high performance and a high power requirement, but is of a low withstand voltage, and a bipolar transistor which is of somewhat lower performance, but a low power requirement and a high withstand voltage. To change the withstand voltages of bipolar transistors, it is necessary to provide transistors having two types of collector impurity concentration. A structure and method for realizing such two types of bipolar transistors on one semiconductor substrate in one process will be described below. Of two types of bipolar transistors simultaneously formed on one semiconductor substrate, a bipolar transistor which is of high performance and a high power requirement, but a low withstand voltage will be referred to as a high-performance bipolar transistor, and a bipolar transistor which is of slightly poorer performance, but is of a low power requirement and a high withstand voltage will be referred to as a high-withstand-voltage bipolar transistor.

According to the present invention, when such two types of bipolar transistors are to be simultaneously formed, if the transistors are of the npn type, then an opening defined in an insulating film for forming a p-type single crystal base region of the high-withstand-voltage bipolar transistor is of a size smaller than an opening defined in an insulating film for forming a p-type single crystal base region of the high-performance bipolar transistor. The p-type single crystal base regions are formed by diffusion or selective epitaxial growth. The difference between the opening sizes or dimensions and the thickness of a CVD film are selected such that the opening in the high-withstand-voltage bipolar transistor is fully filled up, but the opening in the high-performance bipolar transistor is not fully filled up because of the different opening sizes or dimensions.

Then, ions of phosphorus (P) as a p-type impurity are introduced by way of ion implantation. The phosphorus is thus injected into the opening which is not fully filled up. Thereafter, the insulating film is removed, and another insulating film is deposited and subjected to anisotropic dry etching. As a result, the high-performance bipolar transistor and the high-withstand-voltage bipolar transistor can simultaneously be fabricated in exactly the same manner as the conventional fabrication process.

The successive steps of the method according to the present invention are set forth as follows:

(1) openings of different minimum dimensions are formed, and the bases of bipolar transistors are formed by selective epitaxial growth.

(2) A silicon oxide film is formed by LPCVD. At this time, the smaller opening is fully filled. Then, phosphorus ions are introduced for operation with a high current. No phosphorus ions are introduced below the smaller opening.

(3) The insulating film is removed, and side walls are formed.

(4) A polycrystalline silicon film for an emitter electrode is formed, and an emitter is formed in place.

The above and other objects, features, and advantages of the present invention will become apparent from the following description with reference to the accompanying drawings which illustrate examples of the present invention.

### BRIEF DESCRIPTION OF THE DRAWINGS

FIGS. 1A to 1D are vertical cross-sectional views showing a conventional fabrication process of producing a high-withstand-voltage bipolar transistor on a semiconductor substrate;

FIGS. 2A to 2D are vertical cross-sectional views showing the conventional fabrication process of producing a high-performance bipolar transistor on the semiconductor substrate;

FIG. 3 is a vertical cross-sectional view of a semiconductor device according to a first embodiment of the present invention;

FIGS. 4 to 12 are vertical cross-sectional views showing major steps of a process of fabricating the semiconductor device shown in FIG. 3;

FIG. 13 is a vertical cross-sectional view of a semiconductor device according to a third embodiment of the present invention;

FIGS. 14 to 22 are vertical cross-sectional views showing major steps of a process of fabricating the semiconductor device shown in FIG. 13;

FIG. 23 is a vertical cross-sectional view of a high-withstand-voltage vertical npn bipolar transistor in a semiconductor device according to a fourth embodiment of the present invention;

FIG. 24 is a vertical cross-sectional view of a high-performance vertical npn bipolar transistor in the semiconductor device according to the fourth embodiment of the present invention;

FIG. 25 is a plan view of the high-withstand-voltage vertical npn bipolar transistor shown in FIG. 23;

FIG. 26 is a plan view of the high-performance vertical npn bipolar transistor shown in FIG. 24; and

FIGS. 27 to 30 are vertical cross-sectional views showing major steps of a process of fabricating the semiconductor device according to the fourth embodiment.

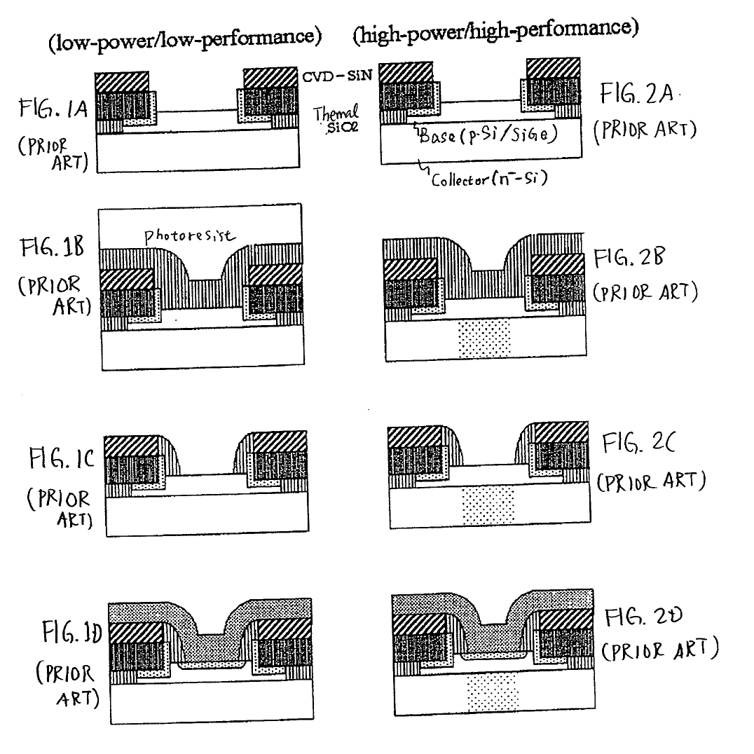

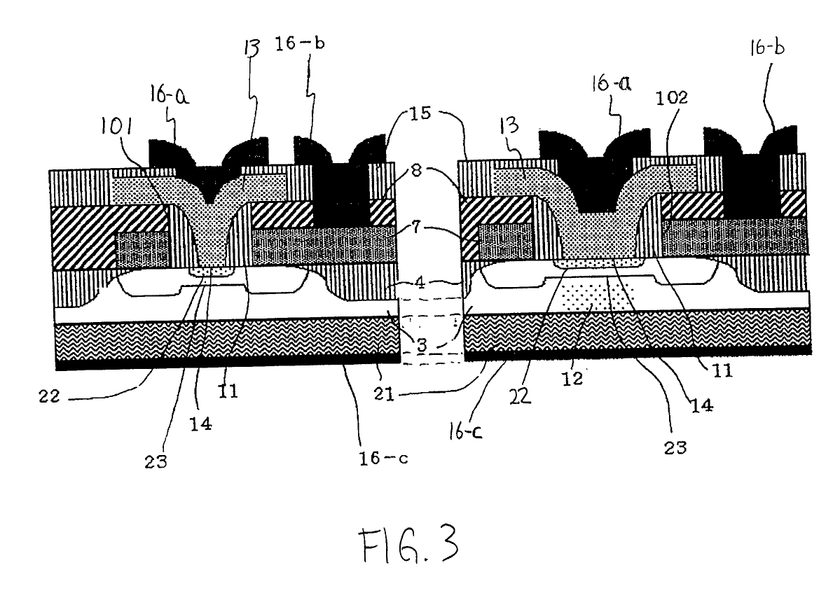

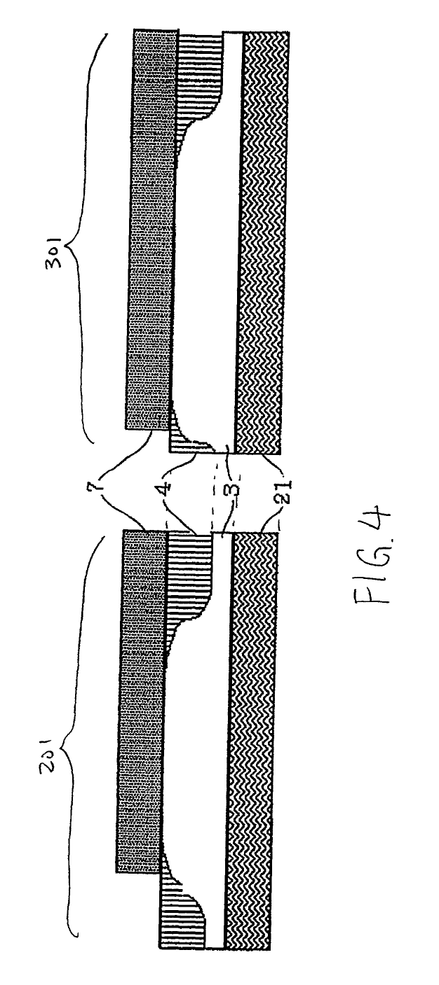

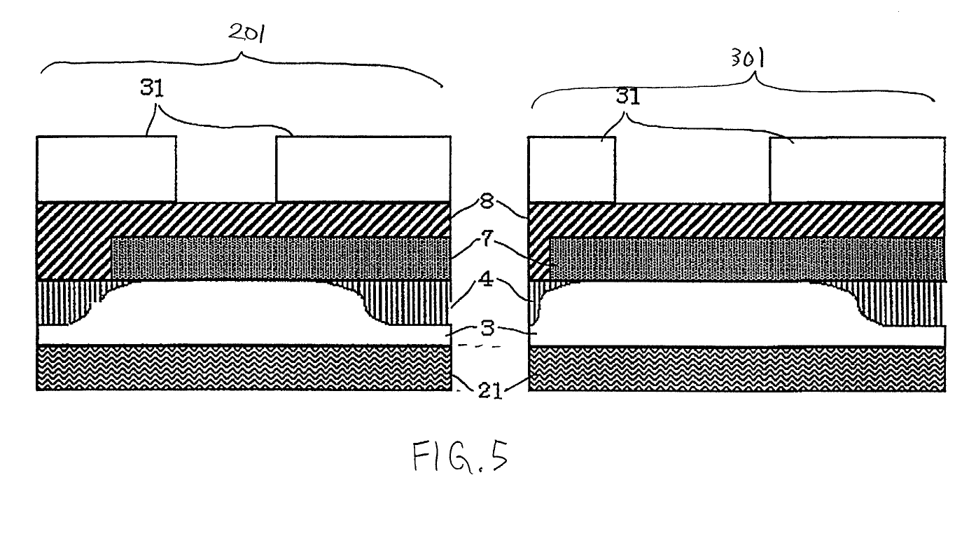

### DESCRIPTION OF THE PREFERRED EMBODIMENTS

As shown in FIG. 3, a semiconductor device according to a first embodiment of the present invention comprises high-withstand-voltage vertical npn bipolar transistor 200 designed to operate with a low current density, and high-performance vertical npn bipolar transistor 300 designed to operate with a high current density. These transistors 200, 300 are separately shown and can be used as discrete elements. However, when transistors 200, 300 are fabricated, they are simultaneously formed on one silicon substrate 21 as shown by broken lines in the figure. After transistors 200, 300 are completed on silicon substrate 21, they are severed from each other and encased in respective packages to produce final products as individual discrete components. While npn bipolar transistors 200, 300 are shown, they are illustrative only, and the present invention is also applicable to pnp bipolar transistors by reversing the conductivity types of the silicon substrate and introduced impurities, as can readily be understood by those skilled in the art.

Each of the discrete components will be described as having collector metal electrode 16c on the reverse side of silicon substrate 21, and comprises a single transistor in one final chip. However, the present embodiment is also applicable to an IC (integrated circuit). If the present embodiment is applied to an IC, then a collector metal electrode may be formed on the face side of the silicon substrate, with a high-withstand-voltage bipolar transistor and a high-performance bipolar transistor being fabricated on one chip.

Silicon substrate 21 comprises an n⁺-type silicon substrate having a crystalline face of face orientation (100), and n⁻-type epitaxial silicon layer 3 for a collector which is disposed on a surface of n⁺-type silicon substrate 21. In the regions of bipolar transistors 200, 300, due to autodoping and thermal diffusion from the buried layer into the growing layer during the growth of n⁻-type epitaxial silicon layer 3, the buried layer region is spread slightly more into n⁻-type epitaxial silicon layer 3 than it is initially disposed. If the effective thickness of n⁻-type epitaxial silicon layer 3 is defined as the thickness of a region whose n-type impurity concentration is 5×10¹⁶ cm⁻³ or less, then the thickness of n⁻-type epitaxial silicon layer 3 is about 0.60 μm. In order to reduce the capacitance between a metal electrode such as base metal electrode 16c and a collector, a silicon oxide film is formed on n⁻-type epitaxial silicon layer 3 by a LOCOS (LOCal Oxidation of Silicon) process. The silicon oxide film thus formed will be referred to as LOCOS film 4.

In each of the regions of bipolar transistors 200, 300, p⁺-type polycrystalline silicon film 7 for a base electrode of the bipolar transistor is selectively formed on n⁻-type epitaxial silicon layer 3 and LOCOS film 4. P⁺-type polycrystalline silicon films 7 in the regions of bipolar transistors 200, 300 have respective openings 101, 102 defined therein. Opening 101 in npn bipolar transistor (high-withstand-voltage bipolar transistor) 200 is smaller than opening 102 in npn bipolar transistor (high-performance bipolar transistor) 300.

P⁺-type polycrystalline silicon films 7 in the regions of bipolar transistors 200, 300 extend inwardly of ends of LOCOS films 4. Each of p⁺-type polycrystalline silicon films 7 has an upper surface covered with silicon nitride film 8 and a side surface covered with silicon oxide film 11.

Intrinsic base region 22 made of p-type single crystal Si is disposed on n⁻-type epitaxial silicon layer 3 in each of openings 101, 102. Outer base region 23 made of p⁺-type single crystal Si is formed below the portion of p⁺-type polycrystalline silicon film 7 that extends inwardly of the end of LOCOS film 4 and connected to intrinsic base region 22. Emitter region 14 made of n⁺-type single crystal Si is disposed in a central region above intrinsic base region 22.

Silicon oxide film 11 serves as side walls of openings 101, 102. In the region of high-performance bipolar transistor 300, collector region 12 made of n-type silicon, to which there is added an impurity whose concentration is higher than the impurity concentration in n⁻-type epitaxial silicon layer 3, is disposed in a region between a base in n⁻-type epitaxial silicon layer 3 directly beneath intrinsic base region 22 and n⁺-type silicon substrate 21. However, such collector region 12 is not disposed in the region of high-withstand-voltage bipolar transistor 200.

In each of bipolar transistors 200, 300, n⁺-type polycrystalline silicon layer 13 for an emitter electrode is disposed on emitter region 14. The semiconductor device also has emitter metal electrode 16a and base metal electrode 16b on the surface formed so far in each of bipolar transistors 200, 300. The semiconductor device further has collector metal electrode 16c on the reverse side thereof. Metal electrodes 16a, 16b, 16c are held in electric contact with n⁺-type polycrystalline silicon layer 13, p⁺-type polycrystalline silicon film 7, and n⁺-type silicon substrate 21. On the face side of the semiconductor device, all regions except for exposed regions of metal electrodes 16a, 16b are covered with silicon oxide film 15.

With the semiconductor device having collector region 12 with the high impurity concentration, high-performance bipolar transistor 300 has a lower withstand voltage, but can operate at a higher speed, than high-withstand-voltage bipolar transistor 200.

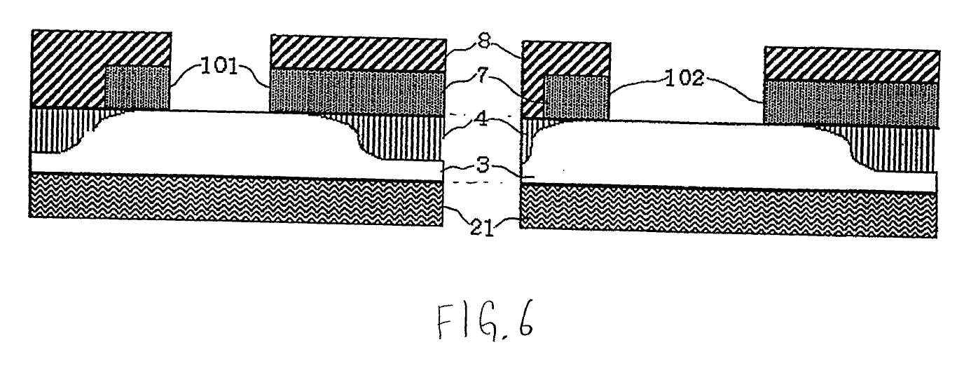

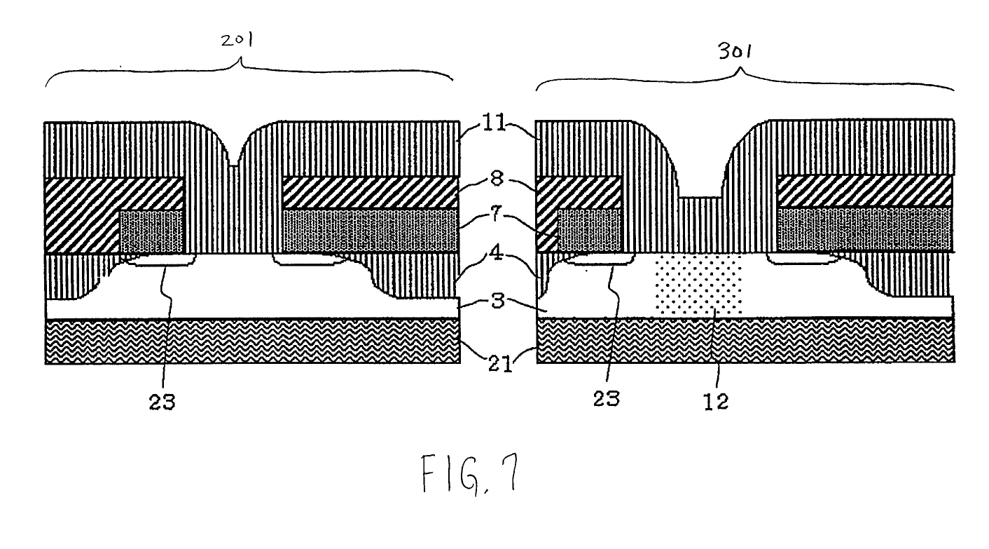

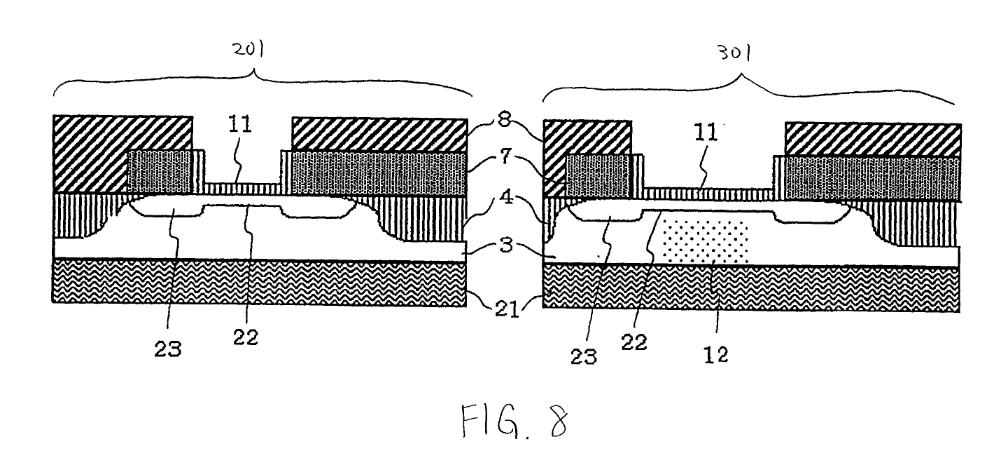

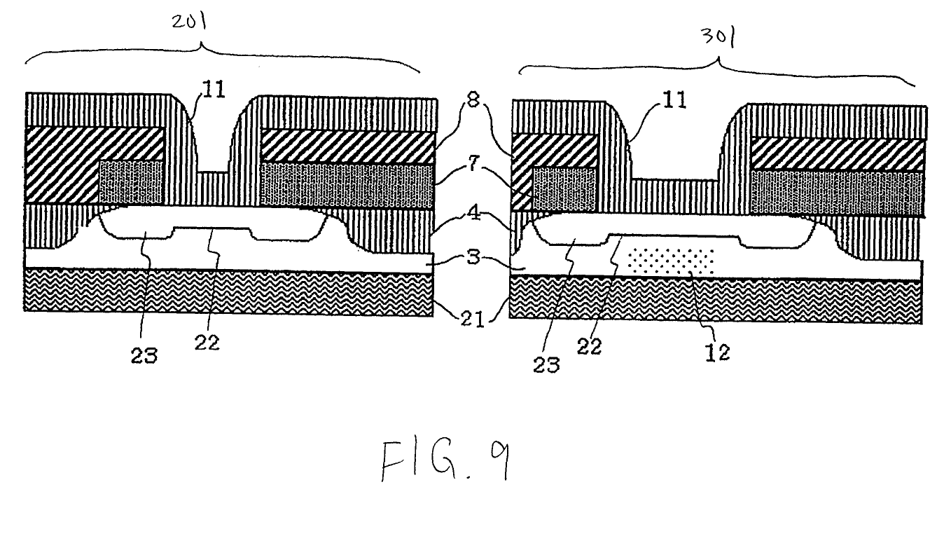

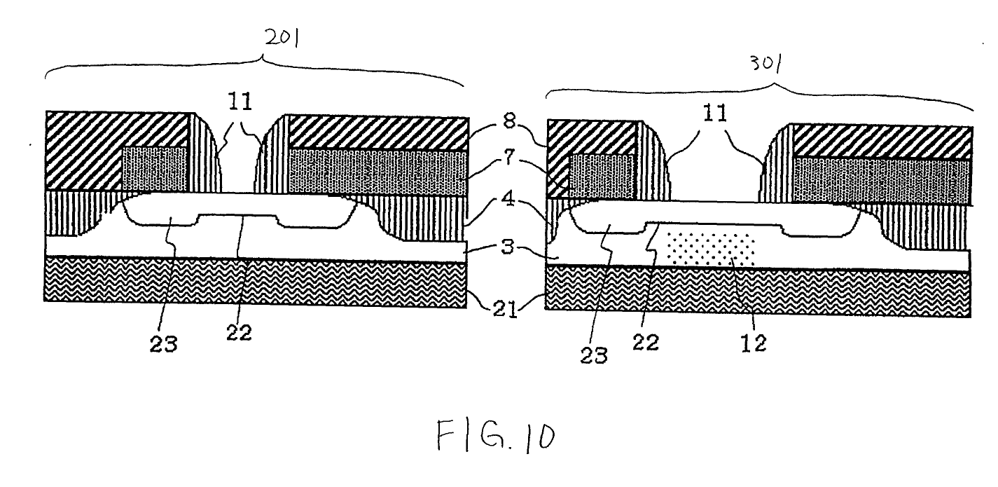

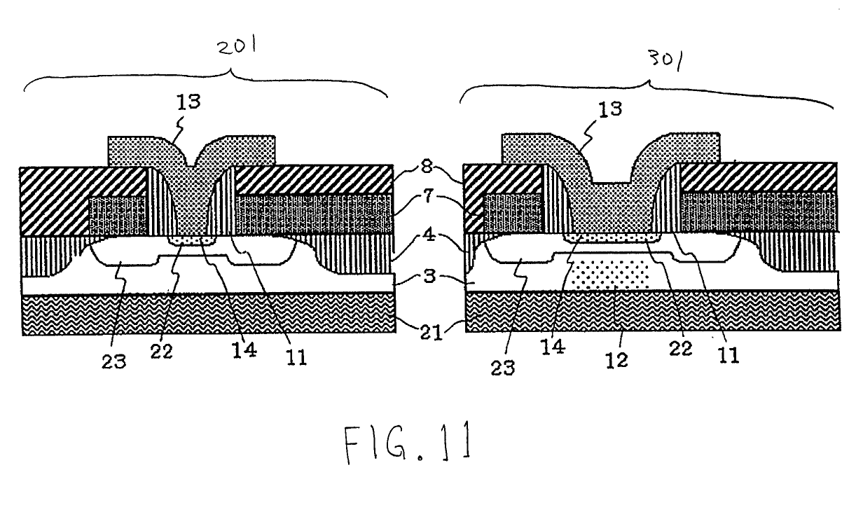

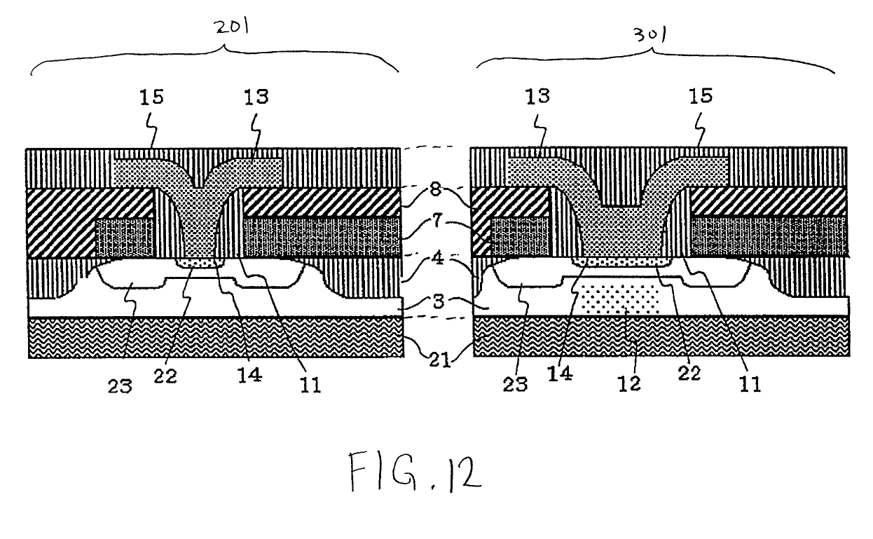

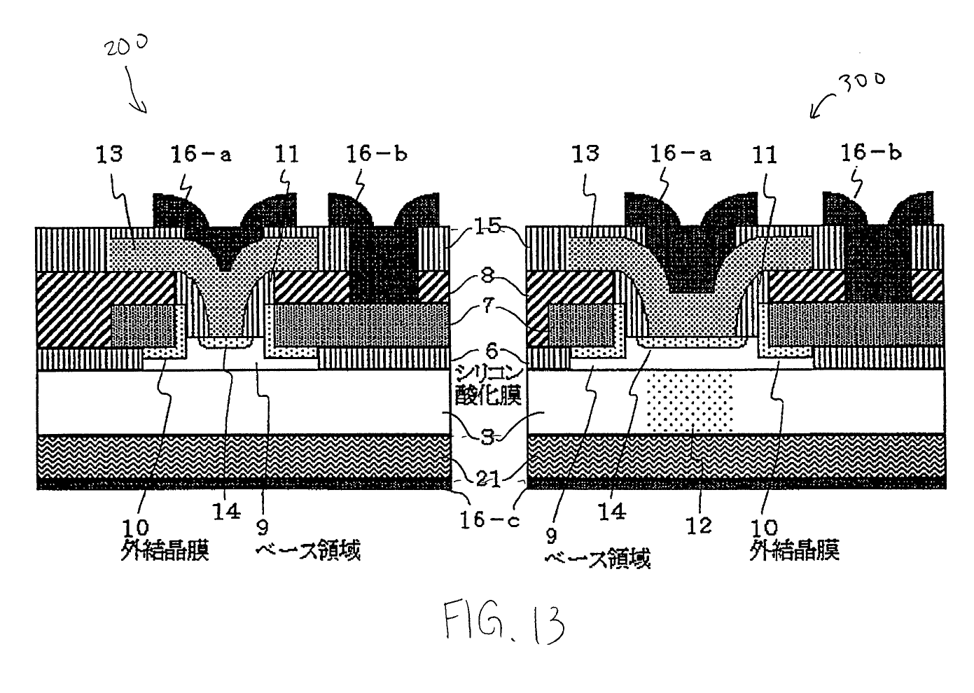

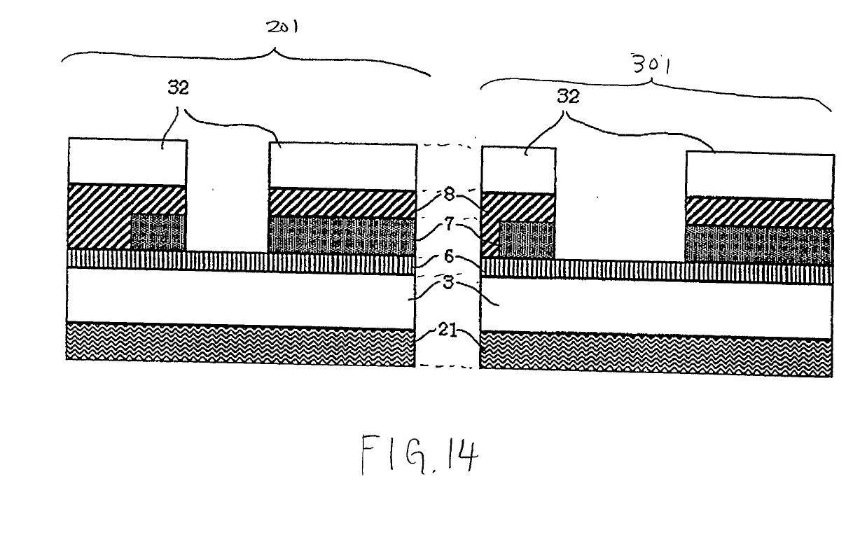

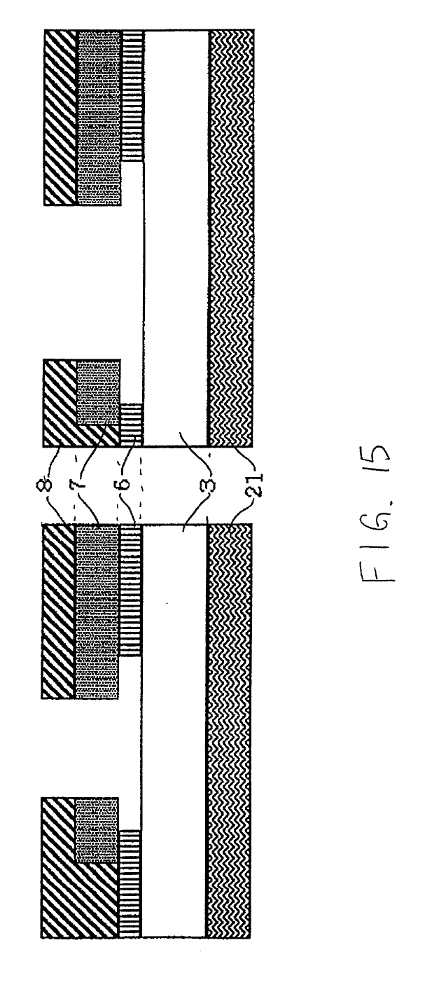

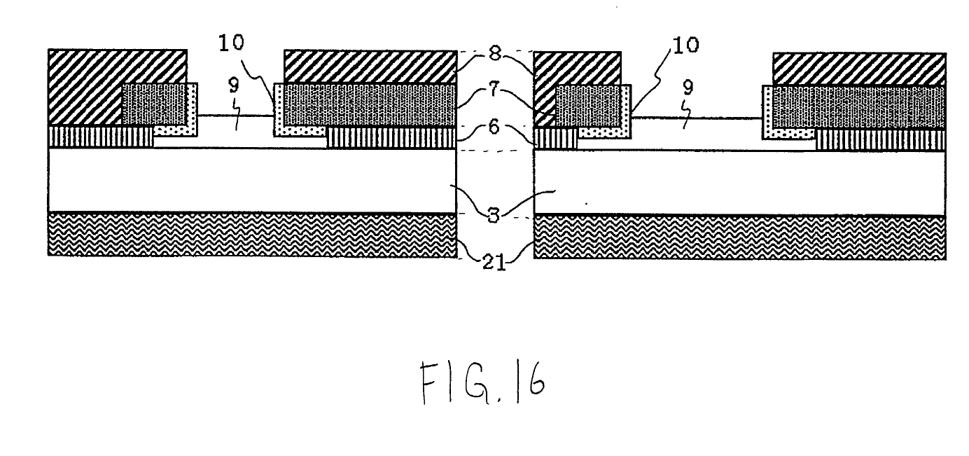

A fabrication process for the above semiconductor device will be described below. FIGS. 4 to 12 show major steps of the fabrication process. Specifically, FIG. 4 shows in vertical cross section a stage in which polycrystalline silicon film 7 is formed. FIG. 5 shows in vertical cross section a stage immediately prior to the formation of openings 101, 102. FIG. 6 shows in vertical cross section a stage immediately after the formation of openings 101, 102. FIG. 7 shows in vertical cross section a stage in which phosphorus is injected in order to increase the impurity concentration in the collector region. FIG. 8 shows in vertical cross section a stage in which a base region has been formed. FIG. 9 shows in vertical cross section a stage in which silicon oxide film 11 is formed by LPCVD (Low Pressure Chemical Vapor Deposition). FIG. 10 shows in vertical cross section a stage in which silicon oxide film 11 is etched by anisotropic dry etching. FIG. 11 shows in vertical cross section a stage in which arsenic-added polycrystalline silicon layer 13 is deposited by LPCVD. FIG. 12 shows in vertical cross section a stage in which the overall assembly or wafer is covered with silicon oxide film 15.

Region 201 is a region where high-withstand-voltage bipolar transistor 200 is to be formed, and region 301 is a region where high-performance bipolar transistor 300 is to be formed.

First, p⁺-type polycrystalline silicon film 7 for a base electrode is formed on silicon substrate 21 in each of regions 201, 302. Specifically, silicon substrate 21 comprises an n⁺-type silicon substrate having a crystalline face of face orientation (100). However, silicon substrate 21 comprises an n⁺-type silicon substrate having another face orientation.

N⁻-type epitaxial silicon layer 3 for a collector is formed by an ordinary vapor phase epitaxial growth process. N⁻-type epitaxial silicon layer 3 is grown at a temperature ranging from 950° C. to 1050° C. with a material gas of SiH₄ or SiH₂Cl₂ and a doping gas of PH₃. During the epitaxial growth, due to autodoping and thermal diffusion from the buried layer into the growing layer, the buried layer region is spread slightly more into the epitaxial layer than it is initially disposed.

If the effective thickness of n⁻-type epitaxial silicon layer 3 is defined as the thickness of a region whose n-type impurity concentration is 1×10¹⁶ cm⁻³ or less, then the thickness of n⁻-type epitaxial silicon layer 3 is about 1.0 μm immediately after the growth thereof. The thickness of n⁻-type epitaxial silicon layer 3 will finally be about 0.9 μm because the impurity from n⁺-type silicon substrate 21 will be diffused by the heat applied in various steps until the transistors are completed.

Then, LOCOS film 4 is formed. Specifically, a thermal oxide film (not shown) having a thickness ranging from 20 nm to 50 nm and a silicon nitride film (not shown) having a thickness ranging from 70 nm to 150 nm are formed on the surface of n⁻-type epitaxial silicon layer 3. Then, a photoresist (not shown) is patterned on the surface formed so far by photolithography, and the silicon nitride film and the silicon oxide film are removed by dry etching. Then, n⁻-type epitaxial silicon layer 3 is etched to form a groove which has a depth, i.e., a depth to which n⁻-type epitaxial silicon layer 3 is etched, that is preferably about half the thickness of an oxide film formed by LOCOS. After the removal of the photoresist, with a device region protected by the silicon nitride film, the assembly is oxidized to form a silicon oxide film, i.e., LOCOS film 4 which has a thickness of about 1.2 μm. The silicon nitride film is then removed by heated phosphoric acid.

Then, an additive-free polycrystalline silicon layer is deposited by LPCVD. The polycrystalline silicon layer preferably has a thickness ranging from 150 nm to 400 nm. In this embodiment, the polycrystalline silicon layer has a thickness of 300 nm. Then, boron (B) is introduced into the polycrystalline silicon layer by way of ion implantation with such an injection energy that the injected boron ions will not pass through the polycrystalline silicon layer. The boron needs to be introduced in a dose large enough to achieve an impurity concentration of about 1×10²⁰ cm⁻³. Prior to the ion implantation, a silicon oxide film having thickness of about 20 nm is formed by CVD. The boron ions are injected through the silicon oxide thus formed with an energy of 10 KeV at a dose of 1×10¹⁶ cm⁻².

Then, the silicon oxide film is fully removed by a solution of hydrogen fluoride with a buffer added thereto. After a photoresist is patterned, the unwanted polycrystalline silicon layer is removed by dry etching. In this manner, p⁺-type polycrystalline silicon film 7 for the base is formed as shown in FIG. 4.

A stage immediately prior to the formation of openings 101, 102 will be described below. After silicon nitride film 8 is formed on p⁺-type polycrystalline silicon film 7, photoresist 31 for forming the openings according to photolithography is patterned. Silicon nitride film 8 is deposited by LPCVD. While the thickness of silicon nitride film 8 is appropriately in the range from 100 nm to 500 nm, it is about 200 nm in the illustrated embodiment. Thereafter, as shown in FIG. 5, openings are formed in photoresist 31 according to ordinary photolithography in areas where intrinsic base regions of vertical bipolar transistors are to be formed.

Thereafter, silicon nitride film 8 and p⁺-type polycrystalline silicon film 7 are successively removed by anisotropic dry etching, using photoresist 31 as a mask. At this time, the surface of n⁻-type epitaxial silicon layer 3 is also removed by a depth of few 10 nm, e.g., 20 nm, by the dry etching, though the removed depth is omitted from illustration. As a result, openings 101, 102 are formed in p⁺-type polycrystalline silicon film 7, as shown in FIG. 6. Opening 101 which is formed in region 201 for high-withstand-voltage bipolar transistor 200 that is designed to operate at a low current density is smaller than opening 102 which is formed in region 301 for high-performance bipolar transistor 300 that is designed to operate at a high current density. Specifically, if these openings are rectangular in shape, then the dimension of the shorter sides of opening 101 is smaller than the dimension of the shorter sides of opening 102. For example, opening 101 has a size of 0.4 μm×8 μm, and opening 102 has a size of 0.6 μm×8 μm.

Then, a stage in which phosphorus is injected in order to increase the impurity concentration in a collector region will be described below. First, as shown in FIG. 7, silicon oxide film 11 is formed by LPCVD to such a thickness that it substantially fully closes opening 101 but does not fully close opening 102. In this case, the thickness is of about 220 nm. The thickness of silicon oxide film 11 which substantially fully closes opening 101 is large enough to prevent phosphorous ions from entering epitaxial silicon layer 3, and the thickness of silicon oxide film 11 which does not substantially fully close opening 102 is small enough to allow phosphorus ions enter epitaxial silicon layer 3. Then, phosphorus ions are applied to the entire surface of the wafer according to ion implantation. Since opening 101 is substantially fully filled up by silicon oxide film 11, no phosphorus ions are introduced into a region below opening 101. On the other hand, because opening 102 is not substantially fully filled up by silicon oxide film 11, phosphorus ions are introduced into a region below opening 102. As a result, high-concentration collector region 12 is formed directly beneath the region where an emitter of high-performance bipolar transistor 300 is to be formed. At this stage, an intrinsic base region and an emitter region have not been formed. Phosphorus ions are introduced with an acceleration energy of 200 KeV in a dose of 4×10¹² cm⁻². Then, the assembly is heated to activate the introduced phosphorus ions. In this manner, the cross-sectional structure shown in FIG. 7 is achieved.

Then, a stage for forming a base region will be described below. After silicon oxide film 11 shown in FIG. 7 is removed, the assembly is subjected to thermal oxidization to oxidize the surface of collector region 12 and the sides of p⁺-type polycrystalline silicon film 7, leaving silicon oxide film 11 having a thickness of about 30 nm on the collector surface. In order to form an intrinsic base region, boron ions are introduced using BF₂ with an acceleration energy of 10 KeV in a dose of 5×10¹³ cm⁻². As a consequence, the cross-sectional structure shown in FIG. 8 is achieved.

Then, as shown in FIG. 9, silicon oxide film 11 is formed by LPCVD to such a thickness that previously formed openings 101, 102 are not fully filled up, but clear recesses are formed in silicon oxide film 11. In this embodiment, the thickness is of about 100 nm.

Then, silicon oxide film 11 is etched by anisotropic dry etching to a depth which is slightly smaller than the thickness of silicon oxide film 11. Thereafter, silicon oxide film 11 is further etched by a solution of hydrogen fluoride with a buffer added thereto to expose intrinsic base region 22 in openings 101, 102, as shown in FIG. 10.

In the stages shown in FIGS. 9 and 10, dimensional variations of the finished assembly can be reduced by employing a process of (1) forming silicon nitride film 8 to a thickness of about 80 nm, for example, according to LPCVD, (2) etching silicon nitride film 8 by a depth slightly larger than thickness of silicon nitride film 8 according to anisotropic dry etching to re-expose the silicon oxide film at the bottom of openings 101, 102, and (3) etching the silicon oxide film with a solution of hydrogen fluoride with a buffer added thereto to expose intrinsic base region 22 in the bottom of openings 101, 102.

Consequently, arsenic-added polycrystalline silicon layer is deposited to a thickness of about 250 nm by LPCVD. Alternatively, after arsenic-free polycrystalline silicon layer is formed by LPCVD, arsenic (As) may be introduced by ion implantation. Thereafter, the polycrystalline silicon layer is patterned according to photolithography and anisotropic dry etching to form n⁺-type polycrystalline silicon layer 13 for an emitter electrode. The assembly is further heated to diffuse arsenic from n⁺-type polycrystalline silicon layer 13, thus forming emitter region 14 made of n⁺-type single crystal Si, as shown in FIG. 11.

Thereafter, the overall wafer surface is covered with a silicon oxide film 15, which is then planarized by CMP (Chemical Mechanical Polishing). The planarizing process may not necessarily be required. As a result, a cross-sectional structure shown in FIG. 12 is obtained.

Then, an opening which reaches n⁺-type polycrystalline silicon layer 13 and an opening which reaches p⁺-type polycrystalline silicon film 7 are formed as openings for forming metal electrodes according to photolithography and anisotropic dry etching. After the photoresist is removed, an aluminum alloy is sputtered and patterned by a photoresist and dry etching, thus forming aluminum alloy electrode 16a for an emitter and aluminum alloy electrode 16b for a base. The reverse side of the assembly is ground to reduce the thickness of the wafer to 400 μm, for example. Then, a metal electrode (aluminum alloy electrode 16c for a collector) is formed on the reverse side of the assembly. Through these stages or steps, the semiconductor device shown in FIG. 3 is fabricated.

In this embodiment, emitter openings are formed in two types of dimensions or sizes, and only the smaller opening is filled up with a CVD insulating film formed after the growth of a base region and phosphorus ions for increasing a collector impurity concentration are not introduced into a transistor with the filled opening. In this manner, it is possible to simultaneously form a high-power, high-performance transistor whose withstand voltage is lower and a low-power, low-performance transistor whose withstand voltage is higher. Heretofore, different ion implantation steps according to photolithography are required to produce such different transistors. However, such different ion implantation steps are dispensed with in the method according to the present invention.

While openings are formed in two types of dimensions for forming emitter regions, it is also possible to form openings in three types of dimensions. In a method according to a second embodiment to be described below, openings are formed in three or more types of dimensions and covered with an insulating film, and phosphorus ions are introduced into the openings.

It is assumed that openings A to C are formed in three types of dimensions. Opening A has a size of 0.3 μm×4 μm, opening B has a size of 0.5 μm×4 μm, and opening C has a size of 0.7 μm×4 μm.

A base region is formed, and the openings are formed in three types of dimensions. After a silicon oxide film is deposited to about 180 nm by LPCVD, phosphorus ions are introduced under “condition: I”. Since opening A is fully filled up with the silicon oxide film, no phosphorus ions are introduced into a semiconductor portion immediately below opening A. Since opening B is not fully filled up with the silicon oxide film, phosphorus ions are introduced into a semiconductor portion immediately below opening B. Since opening C is not fully filled up with the silicon oxide film, phosphorus ions are introduced into a semiconductor portion immediately below opening C.

Thereafter, the silicon oxide film is fully removed by a solution of hydrogen fluoride. After a silicon oxide film is deposited again to about 280 nm by LPCVD, phosphorus ions are introduced under “condition: II” different from the “condition: I”. Since opening A is fully filled up with the silicon oxide film, no phosphorus ions are introduced into the semiconductor portion immediately below opening A. Since opening B is also fully filled up with the silicon oxide film, no phosphorus ions are introduced into the semiconductor portion immediately below opening B. Since opening C is not fully filled up with the silicon oxide film, phosphorus ions are introduced into the semiconductor portion immediately below opening C.

Consequently, no phosphorus ions are introduced into the opening A, phosphorus ions are introduced into the opening B under the “condition: I”, and ions are introduced into the opening C under both the “condition: I” and the “condition: II”. Therefore, transistors three types of junction withstand voltages are fabricated. The “condition: I” and the “condition: II” may be any conditions insofar as they allow phosphorus ions to be introduced in the manner described above.

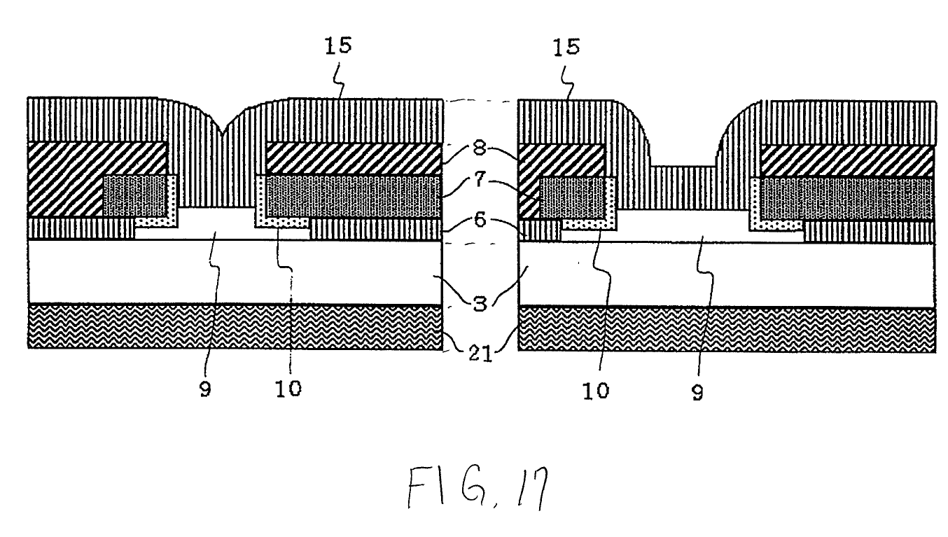

FIG. 13 shows a semiconductor device according to a third embodiment of the present invention. As shown in FIG. 13, the semiconductor device comprises high-withstand-voltage vertical npn bipolar transistor 200 and high-performance vertical npn bipolar transistor 300 which are formed on one silicon substrate 21. The semiconductor device according to the third embodiment differs from the semiconductor device according to the first and second embodiments in that the intrinsic base region is formed by selective epitaxial growth. Different portions of the semiconductor device according to the third embodiment from the semiconductor device according to the first embodiment will be described below. Those parts of the semiconductor device shown in FIG. 13 which are identical to those shown in FIG. 3 are denoted by identical reference characters shown in FIG. 3.

Silicon oxide film 6 is disposed on n⁻-type epitaxial silicon layer 3 for a collector. P⁺-type polycrystalline silicon film 7 for a base electrode of each of the vertical bipolar transistors 200, 300 is selectively formed on silicon oxide film 6. In a region directly beneath p⁺-type polycrystalline silicon film 7, n⁻-type epitaxial silicon layer 3 for a collector is exposed through a first opening of silicon oxide film 6. The opening in high-withstand-voltage vertical npn bipolar transistor 200 is smaller than the opening in high-performance vertical npn bipolar transistor 300. P⁺-type polycrystalline silicon film 7 extends laterally from the ends of the first opening of silicon oxide film 6 into the first opening. P⁺-type polycrystalline silicon film 7 has an upper surface covered with silicon nitride film 8.

In the opening, intrinsic base region 9 of p⁺-type single crystal silicon is disposed on n⁻-type epitaxial silicon layer 3. P⁺-type polycrystalline silicon film 10 is formed on lower and side surfaces of the portion of p⁺-type polycrystalline silicon film 7 which extends into the opening and connected to intrinsic base region 9. Emitter region 14 made of n⁺-type single crystal Si is disposed in a central region above intrinsic base region 9.

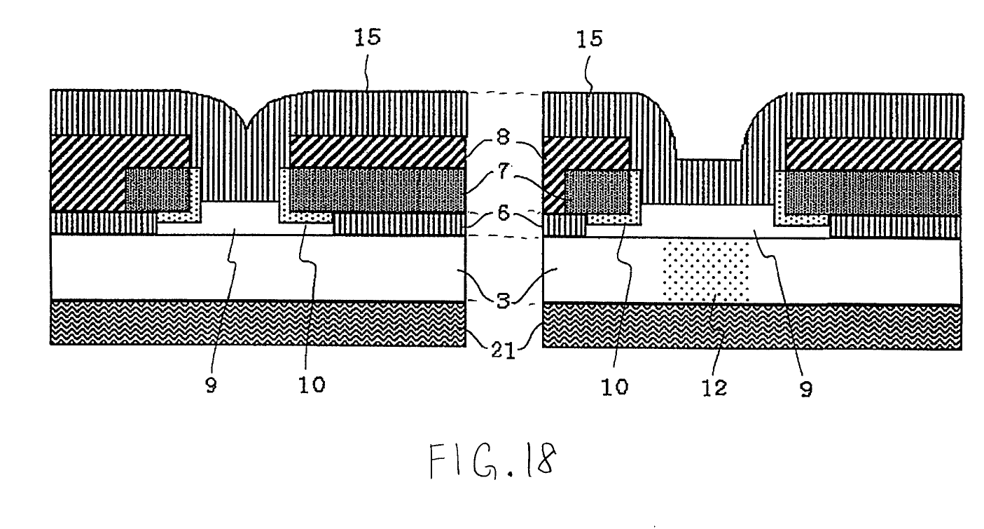

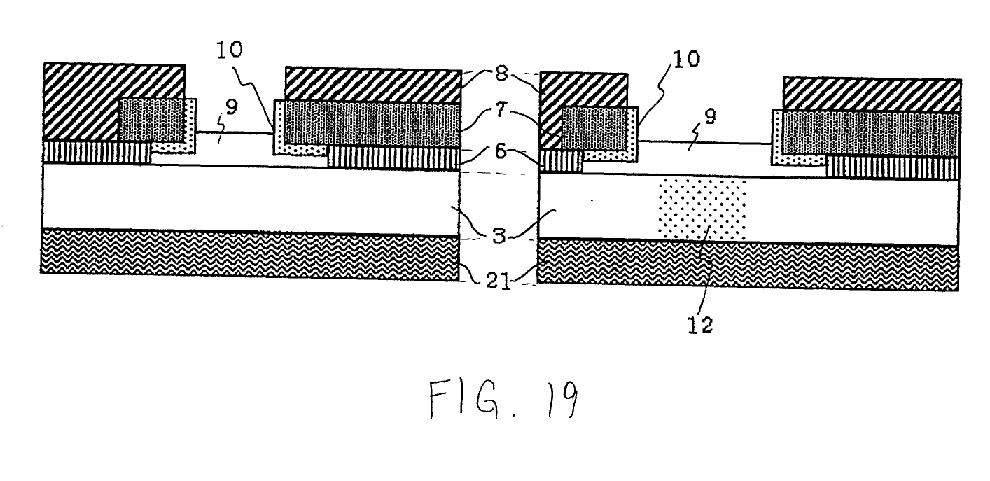

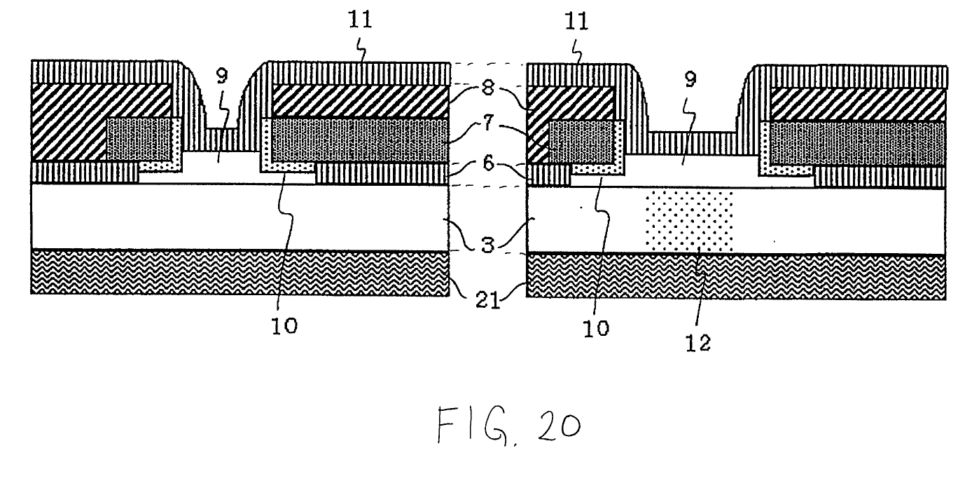

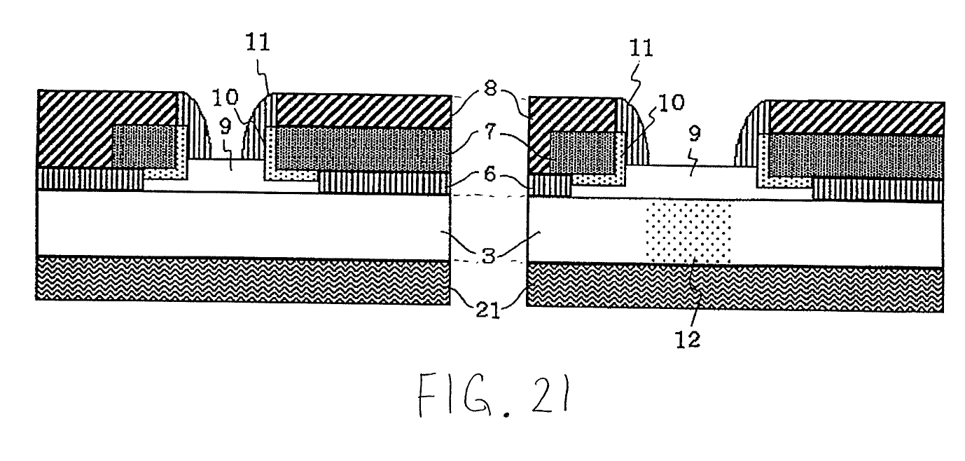

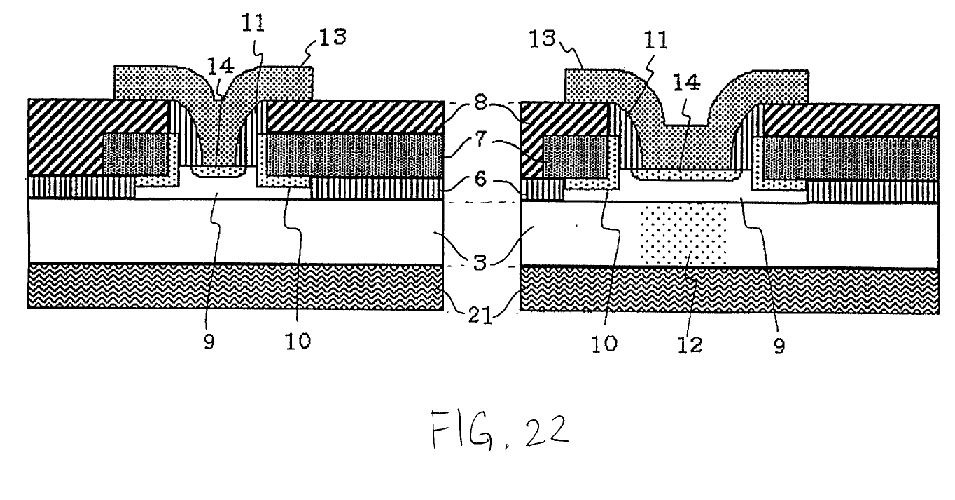

A fabrication process for the semiconductor device according to the third embodiment will be described below. FIGS. 14 to 22 show major steps of the fabrication process. Specifically, FIG. 14 shows in vertical cross section a stage in which openings are formed. FIG. 15 shows in vertical cross section a stage in which a photoresist is removed by an organic solvent. FIG. 16 shows in vertical cross section a stage in which an intrinsic base region of a vertical polar transistor is formed by selective crystal growth. FIG. 17 shows in vertical cross section a stage in which a silicon oxide film is formed by LPCVD. FIG. 18 shows in vertical cross section a stage in which phosphorus is injected to form n-type high-concentration collector region 12 in an opening in high-performance bipolar transistor 300. FIG. 19 shows in vertical cross section a stage in which a silicon oxide film is fully removed by a solution of hydrogen fluoride with a buffer added thereto. FIG. 20 shows in vertical cross section a stage in which a silicon oxide film is deposited by LPCVD. FIG. 21 shows in vertical cross section a stage in which a combination of anisotropic dry etching and wet etching with a solution of hydrogen fluoride with a buffer added thereto is carried out. FIG. 22 shows in vertical cross section a stage in which a phosphorus-added polycrystalline silicon layer is deposited by LPCVD.

For forming an opening, n⁻-type epitaxial silicon layer 3 for a collector is formed on a surface of n⁺-type silicon substrate 21 having a crystalline face of face orientation (100) according to an ordinary process. If the effective thickness of n⁻-type epitaxial silicon layer 3 is defined as the thickness of a region whose n-type impurity concentration is 1×10¹⁶ cm⁻³ or less, then the thickness of n⁻-type epitaxial silicon layer 3 is about 0.6 μm . The thickness of n⁻-type epitaxial silicon layer 3 will finally be about 0.4 μm because the impurity from n⁺-type silicon substrate 21 will be diffused by the heat applied in various steps until the transistors are completed.

Then, LOCOS film (not shown) having a thickness of about 600 nm is formed. A silicon oxide film is formed on the surface of n⁻-type epitaxial silicon layer 3 by CVD or thermal oxidation. The thickness of the silicon oxide film should preferably be slightly smaller than the thickness of a base region to be formed. In this embodiment, the thickness of the silicon oxide film is of about 50 nm.

Then, an additive-free polycrystalline silicon layer is deposited by LPCVD. The polycrystalline silicon layer preferably has a thickness ranging from 150 nm to 400 nm. In this embodiment, the polycrystalline silicon layer has a thickness of 250 nm. Then, boron is introduced into the polycrystalline silicon layer by way of ion implantation with such an injection energy that the injected boron ions will not pass through the polycrystalline silicon layer. The boron needs to be introduced in a dose large enough to achieve an impurity concentration of about 1×10²⁰ cm⁻³. The boron is injected with an energy of 10 KeV in a dose of 1×10¹⁶ cm⁻². After a photoresist is patterned, the unwanted polycrystalline silicon layer is removed by dry etching. In this manner, p⁺-type polycrystalline silicon film 7 is formed.

After silicon nitride film 8 is formed on p⁺-type polycrystalline silicon film 7, a patterning process for the openings is carried out by photolithography. Specifically, silicon nitride film 8 is deposited by LPCVD. While the thickness of silicon nitride film 8 is appropriately in the range from 100 nm to 500 nm, it is about 200 nm in the illustrated embodiment.

Thereafter, as shown in FIG. 14, openings are formed in photoresist layer 32 according to ordinary photolithography in areas where intrinsic base regions are to be formed. Then, silicon nitride film 8 and p⁺-type polycrystalline silicon film 7 are successively removed by anisotropic dry etching, using photoresist film 32 as a mask, forming openings 101, 102 in p⁺-type polycrystalline silicon film 7. As a result, silicon oxide film 6 is exposed at the bottom of openings 101, 102.

As with the first embodiment, opening 101 which is formed for high-withstand-voltage bipolar transistor 200 is smaller than opening 102 which is formed for high-performance bipolar transistor 300. Specifically, opening 101 has a size of 0.3 μm×8 μm, and opening 102 has a size of 0.6 μm×8 μm. In this manner, the cross-sectional structure shown in FIG. 14 is obtained.

Then, photoresist film 32 is removed by an organic solvent. Thereafter, silicon oxide film 6 is etched by a solution of hydrogen fluoride with a buffer added thereto to expose n⁻-type epitaxial silicon layer 3. Since silicon oxide film 6 is laterally retracted by the etching, silicon oxide film 6 becomes wider than the openings in p⁺-type polycrystalline silicon film 7. As a result, as shown in FIG. 15, the lower surface of p⁺-type polycrystalline silicon film 7 is slightly exposed.

Thereafter, an intrinsic base region is formed by selective crystal growth. While the intrinsic base region may be grown by LPCVD or gas-source MBE (Molecular Beam Epitaxy), the intrinsic base region is grown by UHV (Ultra High Vacuum)-CVD in this embodiment. P⁺-type polycrystalline silicon film 10 is formed on lower and side surfaces of p⁺-type polycrystalline silicon film 7. At the same time, a layer of p-type single crystal Si, i.e., intrinsic base region 9, is formed on the exposed portion of n⁻-type epitaxial silicon layer 3. As shown in FIG. 16, p⁺-type polycrystalline silicon film 10 grown from p⁺-type polycrystalline silicon film 7 is connected to the layer of p-type single crystal Si, i.e., intrinsic base region 9, grown on the exposed portion of n⁻-type epitaxial silicon layer 3.

A concentration profile of the impurity, i.e., boron, in intrinsic base region 9, i.e., the layer of p-type single crystal Si, and its film thickness will be described below. The layer of p-type single crystal Si has a thickness of 60 nm. Boron is added to this layer at a concentration of 5×10¹⁸ cm⁻³. Conditions for the UHVCVD growth include, for example, a substrate temperature of 605° C., an Si₂H₆ flow rate of 3 sccm, and a Cl₂ flow rate of 0.03 sccm. A doping agent for boron may be B₂H₆.

Thereafter, silicon oxide film 15 having a thickness of 200 nm, for example, is formed on the wafer surface by LPCVD. At this state, as shown in FIG. 17, opening 101 having a width of 300 nm in region 201 of a high-withstand-voltage bipolar transistor is substantially filled up, and opening 102 having a width of 600 nm in region 301 of a high-speed bipolar transistor remains concave.

Then, as shown in FIG. 18, phosphorus ions are introduced to form high-concentration collector region 12 of n-type silicon in opening 102 in the high-speed bipolar transistor with, for example, an acceleration energy of 200 KeV in a dose of 4×10¹² cm⁻². Then, the assembly is heated to activate the introduced phosphorus ions.

As shown in FIG. 19, silicon oxide film 15 is fully removed by a solution of hydrogen fluoride with a buffer added thereto. Thereafter, as shown in FIG. 20, silicon oxide film 11 is deposited by LPCVD in the same manner as described above with reference to FIG. 9 in the first embodiment, based on a combination of anisotropic dry etching and wet etching with a solution of hydrogen fluoride with a buffer added thereto is carried out. As a result, as shown in FIG. 21, only a central portion of the intrinsic base is exposed.

Then, a phosphorus-added polycrystalline silicon layer is deposited to a thickness of about 250 nm by LPCVD. The impurity added to the polycrystalline silicon layer may be arsenic (As). The polycrystalline silicon layer is then patterned by photolithography and anisotropic dry etching. In this manner, n⁺-type polycrystalline silicon layer 13 is formed. The assembly is then heated to diffuse phosphorus from n⁺-type polycrystalline silicon layer 13 to form emitter region 14 of n⁺-type single crystal Si, as shown in FIG. 22. Subsequent processing details are the same as those of the first embodiment.

The semiconductor device shown in FIG. 13 is completed according to the above fabrication process.

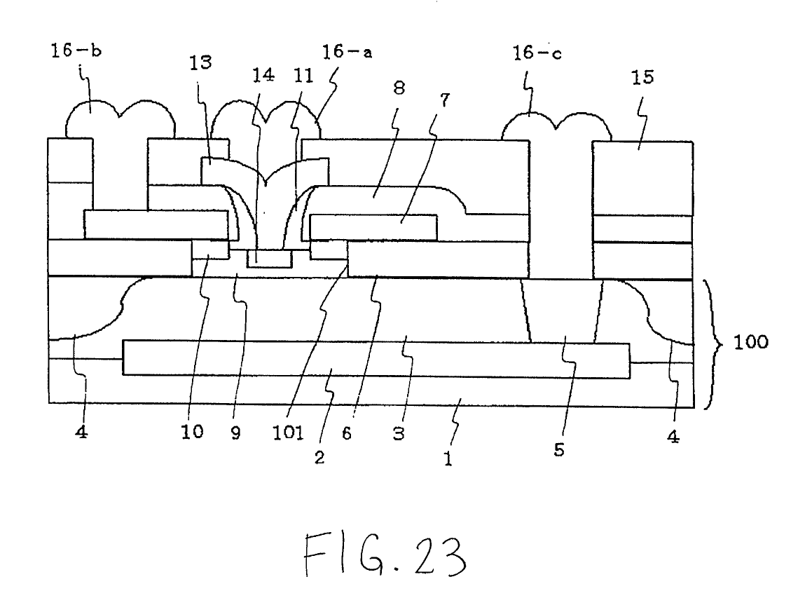

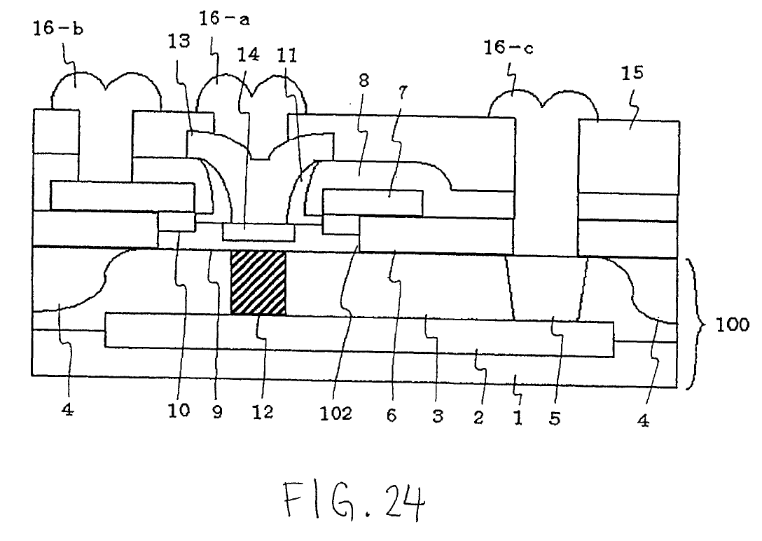

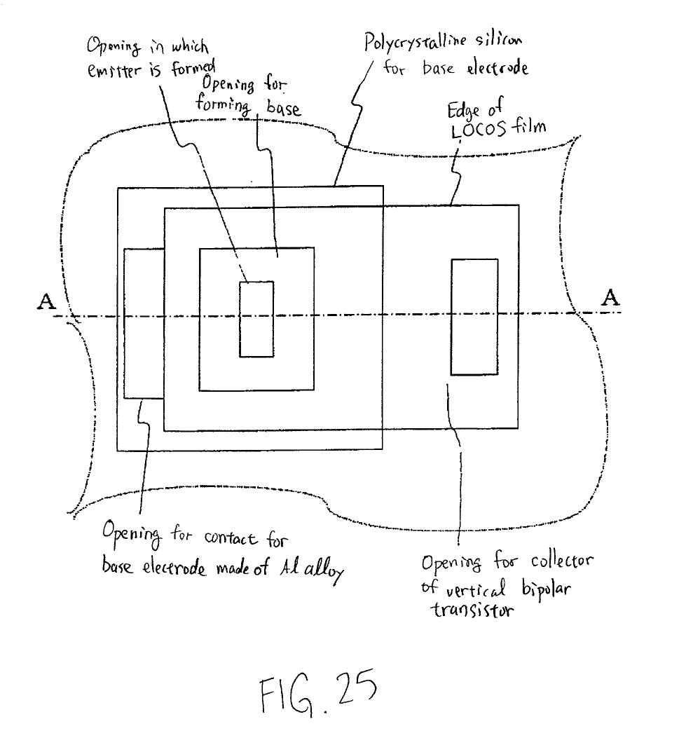

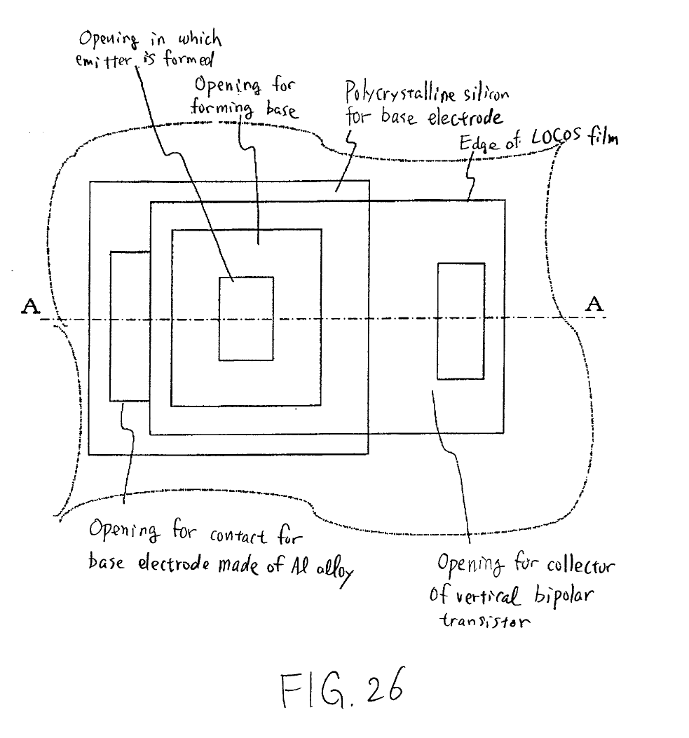

A semiconductor device according to a fourth embodiment of the present invention will be described below. The semiconductor device according to the fourth embodiment comprises a high-withstand-voltage vertical npn bipolar transistor and a high-performance vertical npn bipolar transistor which are simultaneously formed on one silicon substrate in one process. In the fourth embodiment, the present invention is applied to the fabrication of an IC. FIGS. 23 and 25 are a vertical cross-sectional view and a plan view, respectively, of a region where the high-withstand-voltage vertical npn bipolar transistor of the semiconductor device is formed, and FIGS. 24 and 26 are a vertical cross-sectional view and a plan view, respectively, of a region where the high-performance vertical npn bipolar transistor of the semiconductor device is formed.

The semiconductor device according to the fourth embodiment includes p⁻-type silicon substrate 1 having a crystalline face of face orientation (100) and a resistivity ranging from 10 to 20 Ω.cm. N⁺-type buried layer 2 having a thickness of few μm is formed in a portion of the surface of p⁻-type silicon substrate 1. Although not shown, a p⁺-type buried layer for a channel stopper is formed in a portion which will become a device separating region. N⁻-type epitaxial silicon layer 3 for a collector is formed on the surface of n⁺-type buried layer 2 and the surface of p⁻type silicon substrate 1 in a region which is free of n⁺-type buried layer 2. During the epitaxial growth of epitaxial silicon layer 3, the buried layer region is spread slightly more into the epitaxial layer than it is initially disposed due to autodoping and thermal diffusion from n⁺-type buried layer 2 into the growing layer. If the effective thickness of n⁻-type epitaxial silicon layer 3 is defined as the thickness of a region whose n-type impurity concentration is 5×10¹⁶ cm⁻³ or less, then the thickness of n⁻-type epitaxial silicon layer 3 is about 0.60 μm. For device separation, LOCOS film 4 has a depth extending fully through n⁻-type epitaxial silicon layer 3 to a p⁺-type buried layer (not shown). A portion of n⁻-type epitaxial silicon layer 3 serves as a region which is connected to n⁺-type buried layer 2 and to which an impurity is added at a high concentration, the region comprising n⁺-type collector leader region 5. The regions described above are collectively referred to as silicon base 100.

Silicon oxide film 6 is disposed on silicon base 100. P⁺-type polycrystalline silicon film 7 for a base electrode is selectively formed on silicon oxide film 6. N⁻-type epitaxial silicon layer 3 is exposed in openings 101, 102 in silicon oxide film 6 in a region directly beneath p⁺-type polycrystalline silicon film 7. Opening 101 in the high-withstand-voltage bipolar transistor is smaller than opening 102 in the high-performance bipolar transistor.

P⁺-type polycrystalline silicon film 7 extends laterally from the ends of openings 101, 102 of silicon oxide film 6 into openings 101, 102. Side and upper surfaces of p⁺-type polycrystalline silicon film 7 are covered with silicon nitride film 8. In openings 101, 102 in silicon oxide film 6, intrinsic base region 9 of p⁺-type single crystal silicon is disposed on n⁻-type epitaxial silicon layer 3.

P⁺-type polycrystalline silicon film 10 is formed on lower and side surfaces of the portion of p⁺-type polycrystalline silicon film 7 which extends into the opening, i.e., a portion which is not covered with silicon nitride film 8, and connected to intrinsic base region 9. Emitter region 14 made of n⁺-type single crystal silicon is disposed in a central region above intrinsic base region 9. Silicon oxide film 11 serves side walls of openings 101, 102.

In the high-performance bipolar transistor shown in FIG. 24, high-concentration collector region 12 of n-type silicon to which an impurity is added at a concentration higher than the concentration of the impurity in n⁻-type epitaxial silicon layer 3 is formed in a region disposed within n⁻-type epitaxial silicon layer 3 directly below intrinsic base region 9 and between intrinsic base region 9 and n⁺-type buried layer 2. This high-concentration collector region is not present in the high-withstand-voltage bipolar transistor shown in FIG. 23. N⁻-type polycrystalline silicon layer 13 for an emitter electrode is disposed on emitter region 14 of n⁺-type single crystal silicon. In each of the transistors, all the regions described above are covered with silicon oxide film 15.

Metal electrode 16a for an emitter, metal electrode 16b for a base, and metal electrode 16c for a collector are made of an aluminum alloy, and are held in electric contact respectively with n⁺-type polycrystalline silicon layer 13, p⁺-type polycrystalline silicon film 7, and n⁺-type collector leader region 5.

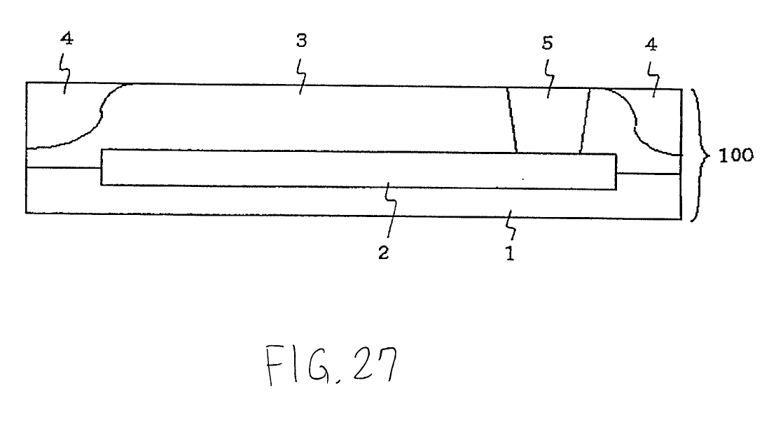

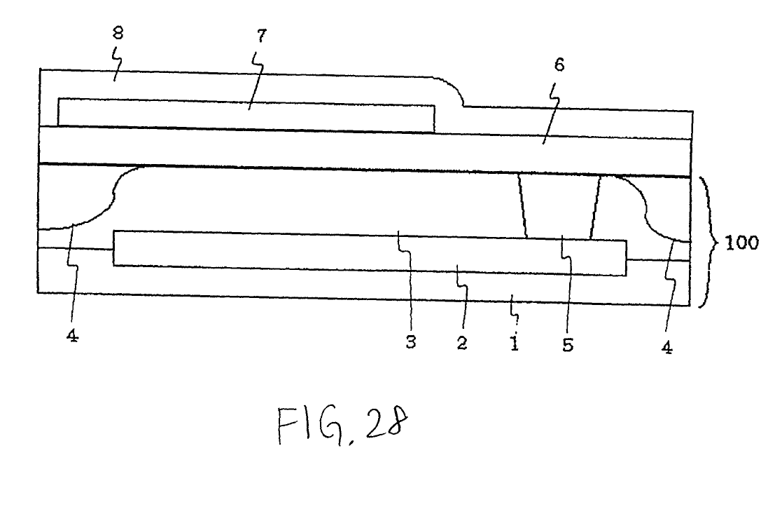

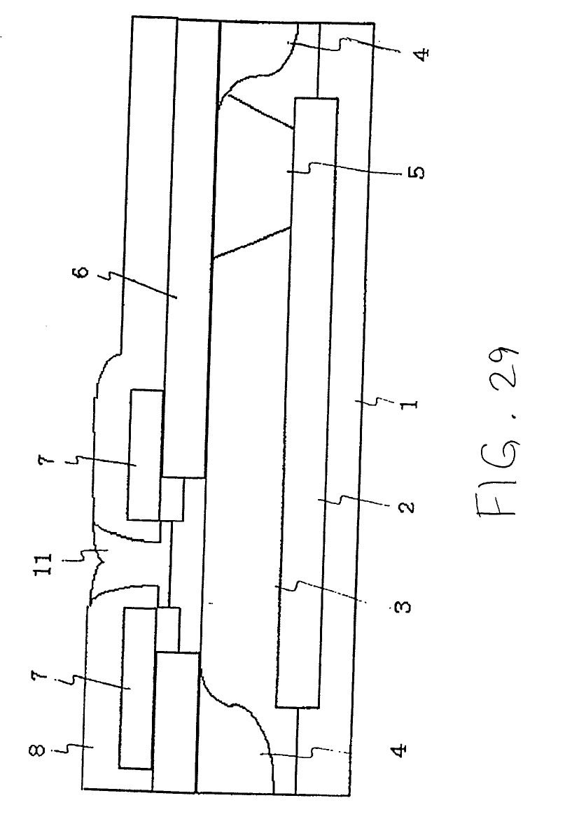

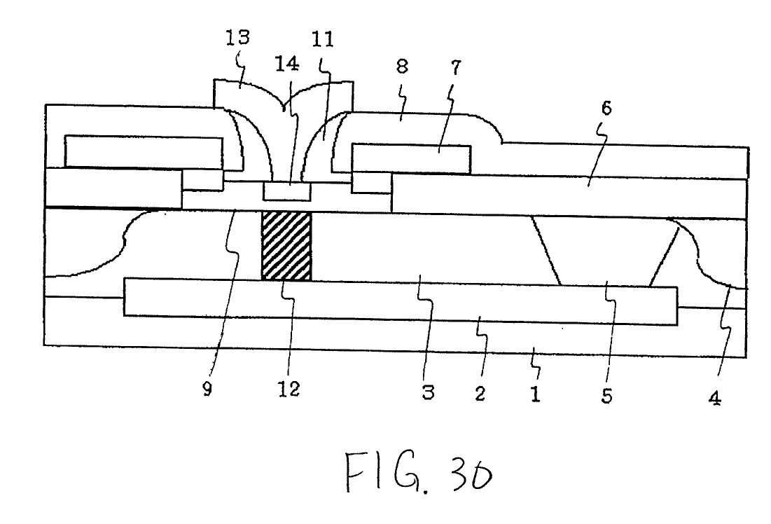

Major steps of a fabrication process for the semiconductor device according to the fourth embodiment will be described below with reference to FIGS. 27 to 30. FIG. 27 shows in vertical cross section a stage in which a silicon base is formed. FIG. 28 shows in vertical cross section a stage in which the surface of the silicon base is covered with a silicone oxide film. FIG. 29 shows in vertical cross section a stage in which a photoresist opening is formed in a portion where an intrinsic base region is formed, of a region where a high-withstand-voltage vertical npn bipolar transistor is formed. FIG. 30 shows in vertical cross section a stage in which a photoresist opening is formed in a portion where an intrinsic base region is formed, of a region where a high-performance vertical npn bipolar transistor is formed. FIGS. 27 and 28 are applicable to both high-withstand-voltage bipolar and high-performance bipolar transistors.

For constructing silicon base 100, there is employed p⁻-type silicon substrate 1 having a crystalline face of face orientation (100), with boron added upon crystal growth such that its resistivity ranges from 10 Ω.cm to 20 Ω.cm. The semiconductor device according to the fourth embodiment may be fabricated if p⁻-type silicon substrate 1 has another face orientation. While the resistivity should preferably be high from the standpoint of reducing the capacitance between the collector and the substrate, no practical problem arises from the resistivity in the above range. If the resistivity is high, since the boron concentration is low, the depletion layer extends sufficiently toward the substrate, resulting in a reduction in the capacitance between the collector and the substrate.

N⁺-type buried layer 2 and p⁺-type buried layer (not shown) are formed in a surface region of p⁻-type silicon substrate 1 as follows:

A silicon oxide film (not shown) is formed on p⁻-type silicon substrate 1 by ordinary CVD or thermal oxidation. The thickness of the silicon oxide film should preferably be several hundreds nm, specifically in the range from 300 nm to 700 nm. In this embodiment, the thickness of the silicon oxide film is of 500 nm. After the silicon oxide film is formed, a photoresist is patterned on the silicon oxide film by ordinary photolithography. The silicon oxide film in a region free of the photoresist is selectively removed by wet etching with a solution of hydrogen fluoride, using the patterned photoresist as an etching mask. Then, the photoresist is removed by an organic solution. For positional registration in a next photolithographic process, the surface of the silicon substrate in the opening in the silicon oxide film is oxidized to a depth ranging from 20 nm to 50 nm.

In order to form an n⁺-type buried region, arsenic is selectively introduced into only a region of p⁻-type silicon substrate 1 where the silicon oxide film is thin, by way of ion implantation. The acceleration energy applied in the ion implantation needs to be low enough for the ions not to pass through the silicon oxide film whose thickness is of 500 nm. The impurity should preferably be introduced at such a dose that the impurity concentration in the buried layer will be on the order of 1×10¹⁹ cm⁻³ so that the collector resistance will not be too high. Specifically, the impurity should be introduced with, for example, an energy ranging from 50 KeV to 120 KeV at a dose ranging from 1×10¹⁵ to 2×10¹⁶ cm⁻². In this embodiment, the impurity is introduced with an energy of 70 KeV at a dose of 5×10¹⁵ cm⁻². Thereafter, the assembly is treated at a temperature ranging from 1000° C. to 1150° C. in order to recover from damage caused by the ion implantation, activate the introduced arsenic and diffuse the impurity. In the embodiment, the assembly is heated at 1100° C. for 2 hours in a nitrogen atmosphere. In this manner, n⁺-type buried layer 2 is formed.

Then, although not shown, a p⁺-type buried layer for a channel stopper is formed. The p⁺-type buried layer for a channel stopper disposed below LOCOS oxide layer 4 is necessary to prevent a leakage between transistors due to the inversion of the conductivity of p⁻-type silicon substrate 1 directly beneath LOCOS oxide layer 4. Specifically, the silicon oxide film that is 500 nm thick is removed in its entirety using a solution of hydrogen fluoride, followed by the formation of a silicon oxide film having a thickness ranging from 50 nm to 250 nm. In this embodiment, the thickness of the silicon oxide film is 100 nm. Thereafter, a photoresist is patterned, boron ions are introduced with 50 KeV at a dose of 1×10¹⁴ cm⁻², the photoresist is removed, and the assembly is heated at 1000° C. for 1 hour in a nitrogen atmosphere to activate the boron, thereby forming the p⁺-type buried layer for a channel stopper.

Thereafter, the silicon oxide film is removed in its entirety, and n⁻-type epitaxial silicon layer 3 for a collector is formed according to an ordinary process. Specifically, n⁻-type epitaxial silicon layer 3 is grown at a temperature ranging from 950° C. to 1050° C. using a material gas of SiH₄ or SiH₂Cl₂ and a doping gas of PH₃. Due to autodoping and thermal diffusion from the buried layer into the growing layer during the growth of n⁻-type epitaxial silicon layer 3, the buried layer region is spread slightly more into n⁻-type epitaxial silicon layer 3 than it is initially disposed. If the effective thickness of n⁻-type epitaxial silicon layer 3 is defined as the thickness of a region whose n-type impurity concentration is 5×10¹⁶ cm⁻³ or less, then the thickness of n⁻-type epitaxial silicon layer 3 is about 0.6 μm. The thickness of n⁻-type epitaxial silicon layer 3 will finally be about 0.4 μm because the arsenic from the buried layer will be diffused by the heat applied in various steps until the transistors are completed. A value suitable for the thickness of n⁻-type epitaxial silicon layer 3 is such that a collector-side end of the depletion layer between the collector and the base reaches n⁺-type buried layer 2 under biasing conditions for operating the transistor. Specifically, n⁻-type epitaxial silicon layer 3 preferably contains an impurity (phosphorus) having a concentration in the range from 5×10¹⁵ to 5×10¹⁶ cm⁻³, and has a thickness ranging from 0.3 μm to 1.3 μm.

The surface of n⁺-type buried layer 2 and n⁺-type buried layer 2 are formed in the manner described above. N⁻-type epitaxial silicon layer 3 is formed in the surface of n⁺-type buried layer 2 and the surface of p⁻-type silicon substrate 1 in the region where n⁺-type buried layer 2 is not formed. The region where n⁻-type epitaxial silicon layer 3 is formed will eventually become the base region of the lateral bipolar transistor and the collection region of the vertical bipolar transistor.

Then, LOCOS film 4 for device separation is formed. First, a thermal oxide film (not shown) having a thickness ranging from 20 nm to 50 nm is formed on the surface of n⁻-type epitaxial silicon layer 3, and a silicon nitride film (not shown) is formed to a thickness ranging from 70 nm to 150 nm. A photoresist (not shown) is patterned by photolithography, and the silicon nitride film and the silicon oxide film are removed by dry etching. N⁻-type epitaxial silicon layer 3 is also etched to form a groove. The depth of the groove, i.e., the depth to which n⁻-type epitaxial silicon layer 3 is etched, should preferably one half of the thickness of LOCOS film 4. After the photoresist is removed, the assembly is oxidized while protecting the device region with the silicon nitride film, thus producing a silicon oxide film for device separation, i.e., LOCOS film 4. LOCOS film 4 preferably has such a thickness that reaches the p⁺-type buried layer for a channel stopper. For example, the thickness of LOCOS film 4 ranges from 300 nm to 1000 nm. In this embodiment, the thickness of LOCOS film 4 is of about 600 nm. The silicon nitride film is removed by heated phosphoric acid.

A portion of n⁻-type epitaxial silicon layer 3 in the vertical bipolar transistor serves as a region which is connected to n⁺-type buried layer 2 and to which an impurity is added at a high concentration, the region comprising n⁺-type collector leader region 5. Similarly, the base electrode forming region in the lateral bipolar transistor has an n⁺-type base leader region connected to n⁺-type buried layer 2.

These leader regions are formed as follows: First, the region is doped with phosphorus by diffusion or ion implantation. Specifically, a photoresist having an opening that corresponds only to n⁺-type collector leader region 5 is formed by photolithography, and phosphorus ions are introduced with an acceleration energy of 100 KeV at a dose of 5×10¹⁵ cm⁻². After the photoresist is removed, the assembly is heated at 1000° C. for 30 minutes in a nitrogen atmosphere to activate the introduced phosphorus and recover the assembly from damage caused by the ion implantation. In this manner, n⁺-type collector leader region 5 is formed.

According to the above process, silicon base 100 is formed as shown in FIG. 27.

Then, the surface of silicon base 100 is covered with silicon oxide film 6. The thickness of silicon oxide film 6 is preferably about twice the thickness of intrinsic base region 9. In this embodiment, the thickness of silicon oxide film 6 is of 100 nm.

Then, an additive-free polycrystalline silicon layer is deposited by LPCVD. The thickness of the polycrystalline silicon layer should preferably range from 150 nm to 350 nm. In this embodiment, the thickness of the polycrystalline silicon layer is of 250 nm. Then, boron is introduced into the polycrystalline silicon layer by way of ion implantation with such an injection energy that the injected boron ions will not pass through the polycrystalline silicon layer. The boron needs to be introduced in a dose large enough to achieve an impurity concentration of about 1×10²⁰ cm⁻³. The boron is injected with an energy of 10 KeV at a concentration of 1×10¹⁶ cm⁻². After a photoresist is patterned, the unwanted polycrystalline silicon layer is removed by dry etching. In this manner, p⁺-type polycrystalline silicon film 7 for a base electrode for the vertical bipolar transistor is formed.

As shown in FIG. 28, silicon nitride film 8 is formed on p⁺-type polycrystalline silicon film 7 by LPCVD. The thickness of silicon nitride film 8 preferably ranges from 100 nm to 500 nm. In this embodiment, the thickness of silicon nitride film 8 is of 200 nm.

Then, photoresist openings are formed in a portion where an intrinsic base region will be formed of the vertical bipolar transistor according to the ordinary photolithography process. At this stage, an opening having a width of 200 nm is formed in the high-withstand-voltage bipolar transistor, and an opening having a width of 500 nm is formed in the high-performance bipolar transistor. Then, silicon nitride film 8 and p⁺-type polycrystalline silicon film 7 are successively removed by anisotropic dry etching, using the photoresist as a mask. As a result, openings of two dimensions are formed.

Then, silicon nitride film 8 is formed by LPCVD. Silicon nitride film 8 needs to be of such a thickness as not to close the previously formed openings. In this embodiment, the thickness of silicon nitride film 8 is of about 50 nm. Then, silicon nitride film 8 is etched by anisotropic dry etching to a depth that is equal to or greater than the thickness of deposited silicon nitride film 8. As a consequence, silicon oxide film 6 is re-exposed at the bottom of the previously formed openings.

Silicon oxide film 6 is etched by a solution of hydrogen fluoride, exposing n⁻-type epitaxial silicon layer 3 for a collector in the vertical bipolar transistor in openings 101, 102. As a result, the lower surface of p⁺-type polycrystalline silicon film 7 is exposed. The etching process causes silicon oxide film 6 to be laterally retracted. An intrinsic base region of the vertical bipolar transistor is then formed by selective epitaxial growth according to UHVCVD. In this embodiment, a heterojunction bipolar transistor with its intrinsic base region made of an SiGe alloy is fabricated. The intrinsic base region is grown at a substrate temperature ranging from 600 to 700° C. using material gases of Si₂H₆ and GeH₄ and a boron doping gas of B₂H₆. By changing the ratio of the flow rates of Si₂H₆ and GeH₄, it is possible to change the ratio of Si and Ge in the SiGe alloy. In order keep selectivity with respect to the silicon oxide film and the silicon nitride film, a trace amount of Cl₂ gas may simultaneously be supplied. A profile of three layers is employed. These layers include, in the order of growth:

1. Si_{0.9}Ge_{0.1} layer with no boron added. The electric impurity concentration is of 1×10¹⁶ cm⁻³ or less. The alloy composition is represented by Si=90 mole % and Ge=10 mole %. The film thickness is of 20 nm.

2. Gradient-composition Si₁₌ₓGeₓ layer with boron added. The boron concentration is of 5×10¹⁸ cm⁻³. Toward the surface, the alloy composition is linearly varied from Si=90 mole % and Ge=10 mole % to Si= 100 mole % and Ge=0 mole %. The film thickness is of 20 nm.

3. Si layer with no boron added. That is, the boron concentration is of 1×10¹⁷ cm⁻³ or less. The alloy composition is represented by Si=100 mole % and Ge=0 mole %. The film thickness is of 30 nm.

As a result, a three-layer polycrystalline film for intrinsic base region 9 for the vertical bipolar transistor is formed on the exposed portion of n⁻-type epitaxial silicon layer 3. At this time, (1) a polycrystalline Si_{0.9}Ge_{0.1} layer with no boron added, (2) a gradient-composition polycrystalline Si₁₋ₓGeₓ layer with boron added, and (3) a polycrystalline Si layer with no boron added are successively formed in the order named from the lower surface of p⁺-type polycrystalline silicon film 7. All these three layers of the polycrystalline film are finally doped into a p-type film by the diffusion of boron from p⁺-type polycrystalline silicon film 7. The p-type polycrystalline film grown from the lower surface of p⁺-type polycrystalline silicon film 7 is connected to intrinsic base region 9 of p-type single crystal silicon that is grown on the exposed portion of n⁻-type epitaxial silicon layer 3.

Then, a silicon oxide film having a thickness of 150 nm is formed on the wafer surface by LPCVD. At this stage, the opening having the width of 200 nm in the high-withstand-voltage bipolar transistor is planarized, whereas the opening having the width of 500 nm in the high-performance bipolar transistor remains concave.

Then, phosphorus ions are introduced to form high-concentration collector region 12 of n-type silicon directly beneath intrinsic base region 9 of the vertical bipolar transistor. The phosphorus ions are introduced with, for example, an acceleration energy of 200 KeV at a dose of 4×10¹² cm⁻². Then, the assembly is heated to activate the introduced phosphorus ions. Since the above opening in high-withstand-voltage bipolar transistor is planarized by being filled up with the silicon oxide film, high-concentration collector region 12 is formed only in the high-performance bipolar transistor.

Thereafter, the assembly is etched by a solution of hydrogen fluoride, and a silicon oxide film is deposited to a thickness of about 150 nm by LPCVD and subjected to anisotropic dry etching to form side walls 11 in the openings. Furthermore, a phosphorus-added polycrystalline silicon layer is deposited to a thickness of about 250 nm by LPCVD, and patterned by photolithography and anisotropic dry etching. In this manner, n⁺-type polycrystalline silicon layer 13 for an emitter electrode for the vertical bipolar transistor is formed. Then, the assembly is heated. At this time, phosphorus is diffused from n⁺-type polycrystalline silicon layer 13 into an Si layer which is the uppermost one of the three layers previously formed by selective epitaxial growth, forming emitter region 14 of n⁺-type single crystal Si.

Then, the overall assembly or wafer is covered with silicon oxide film 15. Openings for forming metal electrodes, i.e., openings reaching n⁺-type polycrystalline silicon layer 13, p⁺-type polycrystalline silicon film 7, and collector leader region 5, respectively, are formed by photolithography and anisotropic dry etching. After the photoresist is removed, an aluminum alloy is sputtering and patterned by a photoresist and dry etching, thus forming aluminum alloy electrode 16a for an emitter, aluminum alloy electrode 16b for a base, and aluminum alloy electrode 16c for a collector, as shown in FIGS. 29 and 30.

Through the above process, the semiconductor device according to the fourth embodiment is fabricated as an integrated circuit comprising at least a high-withstand-voltage bipolar transistor and a high-performance bipolar transistor that are disposed on one silicon substrate.

While preferred embodiments of the present invention have been described using specific terms, such description is for illustrative purposes only, and it is to be understood that changes and variations may be made without departing from the spirit or scope of the following claims.

What is claimed is:

1. A semiconductor device comprising:
a plurality of bipolar transistors designed to exhibit respective optimum electric characteristics at different current densities, said bipolar transistors having respective emitters,
wherein said emitters have greater dimensions for bipolar transistors designed to be used at higher current densities.

2. A semiconductor device according to claim 1, wherein each of said bipolar transistors comprises a vertical bipolar transistor including a single crystal base region which is formed by either diffusion or epitaxial growth.

3. A semiconductor device comprising:
a plurality of vertical bipolar transistors designed to exhibit respective optimum electric characteristics at different current densities and a semiconductor substrate on which said vertical bipolar transistors are disposed,
said vertical bipolar transistors comprising:
respective collector regions,
respective base regions, and
respective emitter regions successively disposed on said semiconductor substrate, said emitter regions having respective substantially rectangular shapes in plan,
wherein said substantially rectangular shapes include shorter sides having greater dimensions for bipolar transistors designed to be used at higher current densities.

4. A semiconductor device according to claim 3, wherein each of said base regions comprises a single crystal base region which is formed by either diffusion or epitaxial growth.

5. A semiconductor device according to claim 4, wherein said vertical bipolar transistors include
a first vertical bipolar transistor operable at a relatively low current density, and
a second vertical bipolar transistor operable at a relatively high current density,
further including an opening corresponding to the emitter region of said first vertical bipolar transistor and having such a dimension as to be fully filled when an insulating film is deposited after said single crystal base region is formed, and
another opening corresponding to the emitter region of said second vertical bipolar transistor and having such a dimension as not to be filled when said insulating film is deposited.

6. A semiconductor device according to claim 5, wherein after said single crystal base region is formed and said insulating film is deposited, ions of an impurity of the same conductivity type as said collector region are introduced to dope said second vertical bipolar transistor with said impurity.

7. A semiconductor device according to claim 5, wherein the concentration of the impurity in the collector region is higher in said second vertical bipolar transistor than in said first vertical bipolar transistor.

8. A semiconductor device used in an integrated circuit comprising, on one chip:
a plurality of vertical bipolar transistors designed to exhibit respective optimum electric characteristics at different current densities, said vertical bipolar transistors having respective single crystal base regions and respective openings for selectively forming said single crystal base regions,
wherein the opening of a vertical bipolar transistor operable at a relatively high current density includes a smaller side having a dimension greater than the dimension of a smaller side of the opening of a vertical bipolar transistor operable at a relatively low current density.

9. A semiconductor device according to claim 8, wherein each of said single crystal base regions is formed by either diffusion or epitaxial growth.

10. A semiconductor device according to claim 8, wherein said opening of the vertical bipolar transistor operable at the relatively low current density has such a dimension as to be fully filled when an insulating film is deposited after said single crystal base region is formed, and said opening of the vertical bipolar transistor operable at the relatively high current density has such a dimension as not to be filled when said insulating film is deposited.

11. A semiconductor device according to claim 10, wherein after said single crystal base region is formed and said insulating film is deposited, ions of an impurity of the same conductivity type as a collector region are introduced to dope said vertical bipolar transistor operable at the relatively high current density, with said impurity.

12. A method of manufacturing a semiconductor device having, on one semiconductor substrate, a first vertical bipolar transistor operable at a relatively low current density and a second vertical bipolar transistor operable at a relatively high current density, the method comprising the steps of:
forming openings for selectively forming single crystal base regions respectively in said first and second vertical bipolar transistors; and
forming single crystal base regions via said openings, the opening in said second vertical bipolar transistor having a size greater than the opening in said first vertical bipolar transistor.

13. A method according to claim 12, wherein said openings are of substantially rectangular shapes and determine emitter areas of the corresponding vertical bipolar transistors, said rectangular shapes having shorter sides whose lengths represent the sizes of said openings.

14. A method according to claim 12, wherein said step of forming single crystal base regions comprises the step of forming single crystal base regions by either diffusion or epitaxial growth.

15. A method according to claim 12, wherein the opening in said first vertical bipolar transistor is of such a size as to be fully filled when the single crystal base region is formed, and the opening in said second vertical bipolar transistor is of such a size as not to be filled when the single crystal base region is formed.

16. A method according to claim 15, further comprising the step of:
after the single crystal base region is formed, introducing ions of an impurity of same conductivity type as a collector region thereby to introduce the impurity only into the region of said second vertical bipolar transistor.

17. A method according to claim 13, wherein the opening in said first vertical bipolar transistor is of such a size as to be fully filled when the single crystal base region is formed, and the opening in said second vertical bipolar transistor is of such a size as not to be filled when the single crystal base region is formed.

18. A method according to claim 17, further comprising the step of:
after the single crystal base region is formed, introducing ions of an impurity of same conductivity type as a collector region thereby to introduce the impurity only into the region of said second vertical bipolar transistor.

19. A method according to claim 12, further comprising the steps of:
growing an insulating film on a device forming surface of said semiconductor substrate after the single crystal base regions are formed; and
introducing ions of an impurity of same conductivity type as a collector region via said insulating film;
the opening in said first vertical bipolar transistor having such a size ass to be substantially filled by said insulating film, and the opening in said second vertical bipolar transistor having such a size as not to be filled by said insulating film.

20. A method according to claim 19, wherein said steps of introducing ions of an impurity comprises the step of:
additionally introducing said impurity only into a collector region of said second vertical bipolar transistor.

21. A method of manufacturing a semiconductor device having, on one semiconductor substrate, a plurality of vertical bipolar transistors designed to exhibit respective optimum electric characteristics at different current densities, the method comprising the steps of:
forming openings for selectively forming base regions respectively in said vertical bipolar transistors;
forming base regions via said openings by way of epitaxial growth;
unselectively forming an insulating film after said base regions are formed; and
thereafter introducing ions of an impurity of the same conductivity type as a collection region;
wherein said openings have greater sizes for bipolar transistors designed to be used at higher current densities.

22. A method according to claim 21, wherein said openings are of substantially rectangular shapes in plan, said rectangular shapes having shorter sides whose lengths represent the sizes of said openings.

23. A method according to claim 21, wherein the opening of the smallest size is substantially filled with said insulating film.

24. A method according to claim 23, wherein the ions of the impurity are not introduced into a collector region of the vertical bipolar transistor which corresponds to the opening of the smallest size.
